(19) United States
(12) Patent Application Publication
(10) Pub. No.: US 2026/0333611 A1
(43) Pub. Date: Oct. 22, 2026

(54) BUSBAR ATTACHED STORAGE

(71) Applicant: Dell Products L.P., Round Rock, TX (US)

(72) Inventors: Padmanabhan Narayanan, Tamil Nadu (IN); Erik Philip Smith, Douglas, MA (US); Robert Neal Beard, Austin, TX (US)

(21) Appl. No.: 19/185,754

(22) Filed: Apr. 22, 2025

(51) Int. Cl. H05K 7/14; H05K 7/20

(52) U.S. Cl. CPC H05K 7/1492; H05K 7/20418; H05K 7/20545

(57) ABSTRACT

An IHS includes: a rack; a busbar; an ITC; and a set of computing devices, in which the rack is a housing for the set of computing devices, in which the busbar is affixed to a rear side of the rack, in which the busbar includes an enclosure comprising a storage device and a heat sink, in which the storage device includes a NOS that manages an operation of the ITC, in which, when the ITC is plugged into the busbar, a NOS-grub of the ITC communicates with the storage device to boot up the NOS from the storage device to make the ITC operable, and in which the heat sink provides a temperature management to the storage device at least when the NOS is booted up.

### BACKGROUND

Devices are often capable of performing certain functionalities that other devices are not configured to perform or are not capable of performing. In such scenarios, it may be desirable to adapt one or more systems to enhance the functionalities of devices that cannot perform those functionalities.

### BRIEF DESCRIPTION OF DRAWINGS

Certain embodiments disclosed herein will be described with reference to the accompanying drawings. However, the accompanying drawings illustrate only certain aspects or implementations of one or more embodiments disclosed herein by way of example and are not meant to limit the scope of the claims.

FIG. 1.1 shows/illustrates a diagram of a system in accordance with one or more embodiments disclosed herein.

FIG. 1.2 shows a diagram of an information handling system (IHS) (from an isometric view) in accordance with one or more embodiments disclosed herein.

FIG. 1.3 shows a diagram of a rack of the IHS (from a front view) in accordance with one or more embodiments disclosed herein.

FIG. 1.4 shows a diagram of the rack (from an isometric view) in accordance with one or more embodiments disclosed herein.

FIG. 1.5 shows a diagram of the rack (from a front view) in accordance with one or more embodiments disclosed herein.

FIG. 1.6 shows a diagram of the rack (from a front view) in accordance with one or more embodiments disclosed herein.

FIG. 1.7 shows (a) a diagram of a busbar (from an isometric view) and (b) a diagram of an information technology component (ITC) (from an isometric view) in accordance with one or more embodiments disclosed herein.

FIG. 1.8 shows (a) a diagram of the busbar (from an isometric view) and (b) a diagram of the ITC (from an isometric view) in accordance with one or more embodiments disclosed herein.

FIG. 1.8A shows a cross-section (or a cross-sectional shape) of an enclosure in accordance with one or more embodiments disclosed herein.

FIG. 1.8B shows a cross-section (or a cross-sectional shape) of a rail in accordance with one or more embodiments disclosed herein.

FIG. 1.9 shows (a) a diagram of the busbar (from an isometric view) and (b) a diagram of the ITC (from an isometric view) in accordance with one or more embodiments disclosed herein.

FIG. 1.10 shows (a) a diagram of the busbar (from an isometric view) and (b) a diagram of the ITC (from an isometric view) in accordance with one or more embodiments disclosed herein.

FIG. 1.11 shows/illustrates a diagram of ITC plugged into the busbar in accordance with one or more embodiments disclosed herein.

FIG. 2 shows a method for managing a busbar attached storage in accordance with one or more embodiments disclosed herein.

FIG. 3 shows a method for managing a busbar attached storage in accordance with one or more embodiments disclosed herein.

FIG. 4 shows a diagram of a computing device in accordance with one or more embodiments disclosed herein.

### DETAILED DESCRIPTION

Specific embodiments disclosed herein will now be described in detail with reference to the accompanying figures. In the following detailed description of the embodiments disclosed herein, numerous specific details are set forth in order to provide a more thorough understanding of one or more embodiments disclosed herein. However, it will be apparent to one of ordinary skill in the art that the one or more embodiments disclosed herein may be practiced without these specific details. In other instances, well-known features have not been described in detail to avoid unnecessarily complicating the description.

In the following description of the figures, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment, which may be implemented in addition to, in conjunction with, or in place of the embodiments described with regard to a corresponding like-named component in any other figure.

Throughout this application, elements of figures may be labeled as A to N. As used herein, the aforementioned labeling means that the element may include any number of items, and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure, and the number of elements of the second data structure, may be the same or different.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase “operatively connected” may refer to any direct connection (e.g., wired directly between two devices or components) or indirect connection (e.g., wired and/or wireless connections between any number of devices or components connecting the operatively connected devices). Thus, any path through which information may travel may be considered an operative connection.

In general, organizations'networking portfolios include 1 rack unit (RU) and/or 2RU network switches that support a wide range of interface speeds (e.g., 1 Gigabit per second to 800 Gigabits per second), providing users/customers with a wide range of connectivity options. Most of these network switches may include a computer-on-modules (COM) Express central processing unit (CPU) module that is plugged into a network switch board (e.g., the main board of the switch), which may house/host a network processing unit (NPU) (e.g., an application-specific integrated circuit (ASIC)), a field-programmable gate array (FPGA), a complex programmable logic device (CPLD), and/or other data plane computing devices/components, in order to decouple the COM-Express CPU module from a related switch board. In some cases, the COM-Express CPU module may include an embedded multimedia card (eMMC) (e.g., to execute diagnostics tests (upon a user's request) if there is an issue with the corresponding network switch) and a storage device (e.g., a solid-state drive (SSD), to execute an Open Network Install Environment (ONIE) agent to install a related network operating system (NOS)).

From a different perspective, when recently detected/reported network switch failures, SSD usages, SSD failures/issues (e.g., firmware related issues, serial advanced technology attachment (SATA) cable related issues, etc.), and return material authorization (RMA) processes are investigated, one may observe the following trends: (i) network switches fail for a multitude of reasons, such as CPU errata, dynamic random-access memory (DRAM) issues, SSD failures, switchport cage connector issues, management port/console issues, etc., (ii) customers/users are increasingly concerned about controlling configuration data (e.g., passwords, usernames, Internet Protocol (IP) addresses, etc.) and preventing data leaks that can result from returning a faulty switch for an RMA process (the customers may want to perform a secure erase of the data, or (based on the sensitivity of the data) may want to remove and destroy the SSD before sending the corresponding network switch to a related vendor/manufacturer, where both options may increase time and material cost), (iii) when a network switch needs to be swapped due to a fault (related to switch), a newer (or an identical) network switch is typically plugged into a related rack as a replacement and cables (e.g., optical cables) are reconnected to the newer network switch (once installed into the rack, the newer network switch may undergo an ONIE installation (or a zero-touch provisioning (ZTP)) process, which may take several minutes, to get to a state where the newer network switch gains the functionalities of the replaced network switch), (iv) customers have a wide range of SSD capacity requirements (indicating that it may be great if customers also get to choose/configure (a) the SSD vendor and (b) the SSD's capacity), (v) SSD failures typically result in an RMA process, as performing a field replacement is currently not possible for customers (where (a) performing a field replacement (of a network switch by a user) may void the switch's warranty and (b) letting users to choose their vendor may result in reducing a corresponding technical assistance center's (TAC) efforts in debugging SSD failures), (vi) customers mostly use open rack version 3 (ORV3) racks as their top choice, and (vii) non-volatile memory express (NVMe) M.2 SSDs (e.g., SSDs that use both M.2 physical form factor and the NVMe protocol) are the top choice in most network switches.

For at least the reasons and/or observations discussed above and without requiring resource-intensive efforts (e.g., time, engineering, etc.), a fundamentally different solution/framework is needed (e.g., a busbar attached storage (BAS) that (a) addresses customer concerns with respect to, at least, sensitive data leakage and (b) improves network switch replacement time).

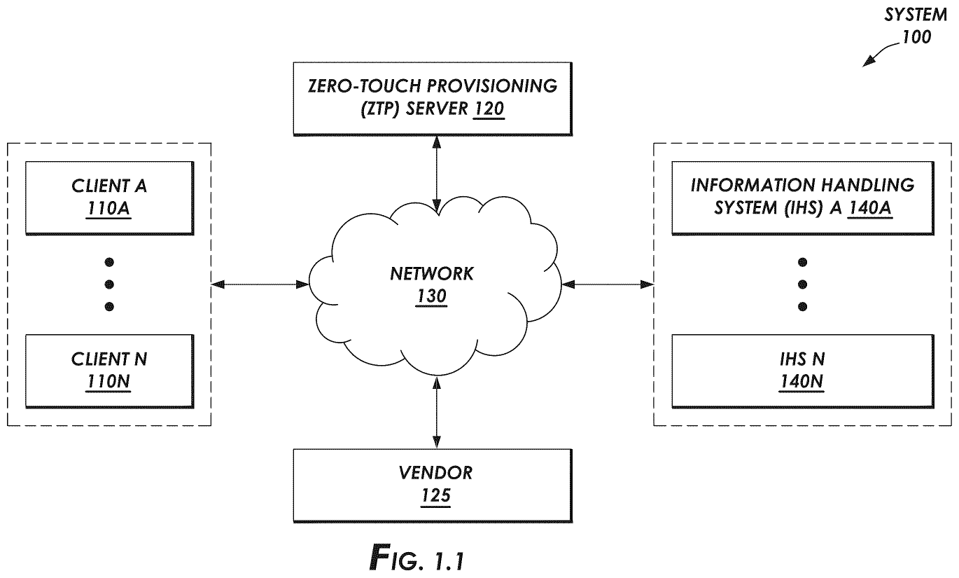

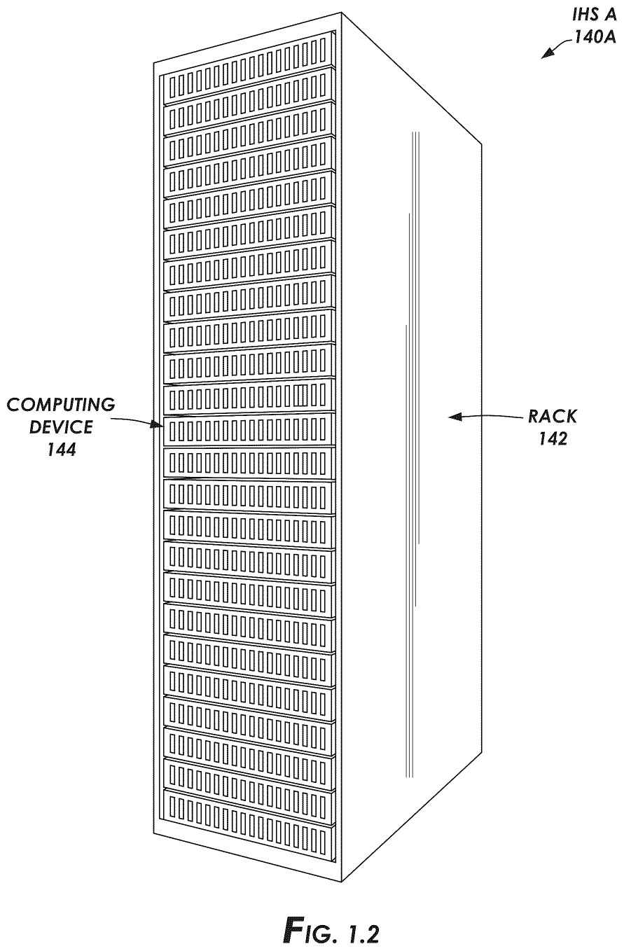

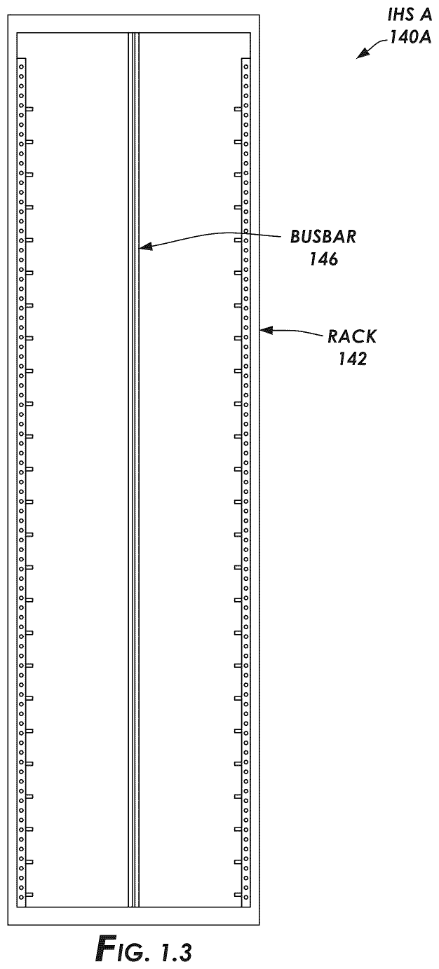

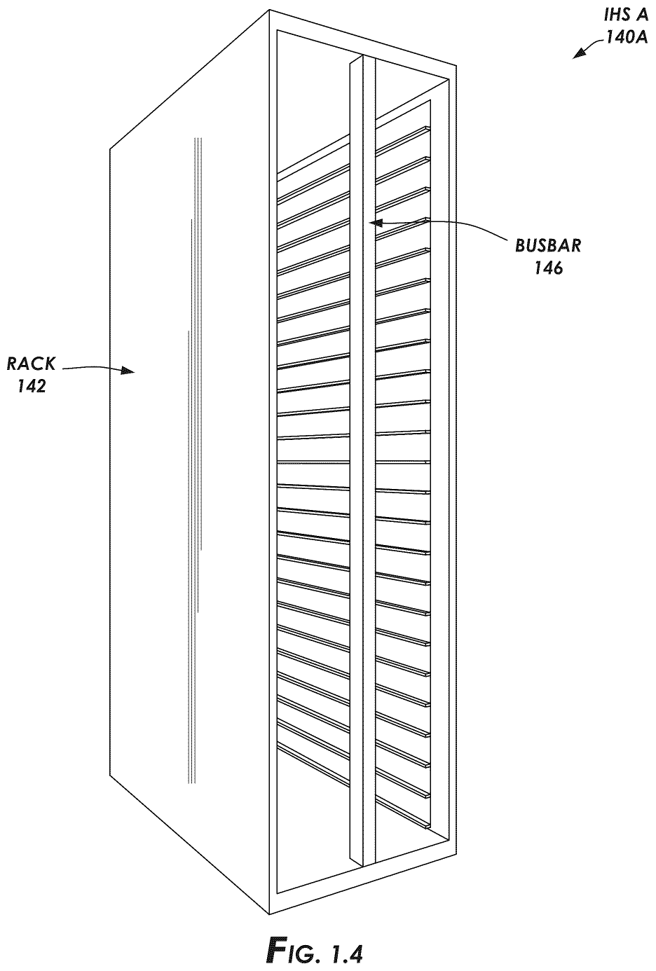

Embodiments disclosed herein relate to (a) a BAS and (b) methods and systems to manage the BAS. As discussed below, one or more embodiments disclosed herein advantageously ensure that: (i) a storage device (e.g., an NVMe M.2 SSD) is attached/affixed to a busbar (of a corresponding rack) such that the storage device can be operatively connected to an ITC that has a socket (e.g., an M.2 socket at a fixed distance from the ITC's connector(s) (e.g., power connectors, power links, etc.) (see FIG. 1.7-1.10) (said another way, the main storage device (e.g., an SSD that stores sensitive data, the main NOS that manages an operation of the ITC, etc.) of the ITC is removed and affixed (within an enclosure, see e.g., FIG. 1.7) to the busbar, where the busbar can accommodate the enclosure); (ii) the main NOS can be configured to be executed entirely off the BAS (as “BAS-NOS”) or may selectively use the BAS only to store sensitive data (e.g., user credentials, network packet traces that may include sensitive user data, data related to custom containers or business logic, etc.); (iii) the time consuming process of replacing a faulty network switch with a newer network switch (where, traditionally, the main storage device is located within the “faulty” network switch and to replace that switch with a newer one, the user may need to perform actions that take time (e.g., removing screws, removing optical cables, removing the faulty switch from the rack, deploying the newer switch in place, attaching the optical cables, powering on the newer switch, following a configuration process with a ZTP server to become operable like the replaced switch, etc.)) is minimized as (a) the main NOS (which may be around several gigabytes (GBs) in size) is now located outside of a corresponding ITC (that may need to be replaced) (or located inside of the BAS, see FIG. 1.11) and (b) the main storage device is attached to the busbar (instead of keeping the main storage device inside of the network switch); (iv), based on (iii), the replacement process and the boot up process of a newer ITC would be quicker (where the user does not need to spend so much time to download the image and to configure all the relevant data packages necessary to make the newer ITC operable); and/or (v) if the main NOS (available in the BAS as “BAS-NOS”) is functional, the newer ITC (via its NOS grand unified bootloader (grub) (which is a few megabytes (MBs) in size) can use the main NOS to boot itself up and make itself operable (without going through the configuration process with the ZTP server).

The following describes various embodiments disclosed herein.

FIG. 1.1 shows a diagram of a system (100) in accordance with one or more embodiments disclosed herein. The system (100) includes any number of clients (e.g., Client A (110A), Client N (110N), etc.), any number of IHSs/nodes (e.g., Server A (140A), Server N (140N), etc.), a vendor (125), a ZTP server (120), and a network (130). The system (100) may include additional, fewer, and/or different components without departing from the scope of the embodiments disclosed herein. Each component may be operably/operatively connected to any of the other components via any combination of wired and/or wireless connections. Each component illustrated in FIG. 1.1 is discussed below.

In one or more embodiments, the clients (e.g., 110A, 110N, etc.), the vendor (125), the IHSs (e.g., 140A, 140N, etc.), the ZTP server (120), and the network (130) may be (or may include) physical hardware or logical devices, as discussed below. While FIG. 1.1 shows a specific configuration of the system (100), other configurations may be used without departing from the scope of the embodiments disclosed herein. For example, although the clients (e.g., 110A, 110N, etc.) and the IHSs (e.g., 140A, 140N, etc.) are shown to be operatively connected through a communication network (e.g., 130), the clients (e.g., 110A, 110N, etc.) and the IHSs (e.g., 140A, 140N, etc.) may be directly connected (e.g., without an intervening communication network).

Further, the functioning of the clients (e.g., 110A, 110N, etc.) and the IHSs (e.g., 140A, 140N, etc.) is not dependent upon the functioning and/or existence of the other components (e.g., devices) in the system (100). Rather, the clients and the servers may function independently and perform operations locally that do not require communication with other components. Accordingly, embodiments disclosed herein should not be limited to the configuration of components shown in FIG. 1.1.

As used herein, “communication” may refer to simple data passing, or may refer to two or more components coordinating a job. As used herein, the term “data” is intended to be broad in scope. In this manner, that term embraces, for example (but not limited to): a data stream (or stream data), data chunks, data blocks, atomic data, emails, objects of any type, files of any type (e.g., media files, spreadsheet files, database files, etc.), contacts, directories, sub-directories, volumes, etc.

As used herein, a “volume” may be analogous to a logical unit number in a SAN, in which a volume may be a subset of a storage system's capacity presented by a storage node of the storage system as a local block device. A volume's data may be evenly distributed across all storage resources of the storage system, for example, according to a data layout selected for the storage system.

In one or more embodiments, although terms such as “document”, “file”, “segment”, “block”, or “object” may be used by way of example, the principles of the present disclosure are not limited to any particular form of representing and storing data or other information. Rather, such principles are equally applicable to any object capable of representing information.

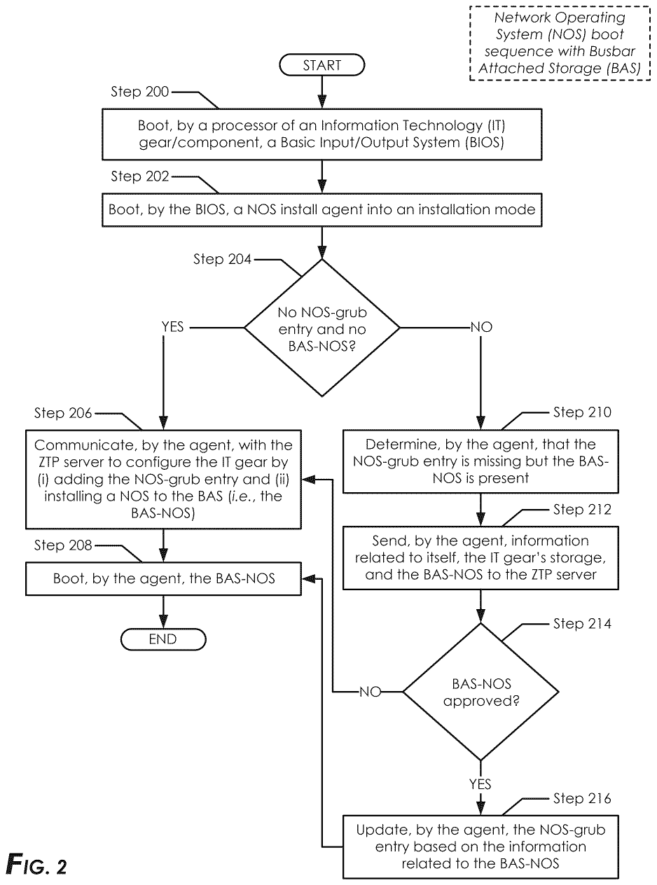

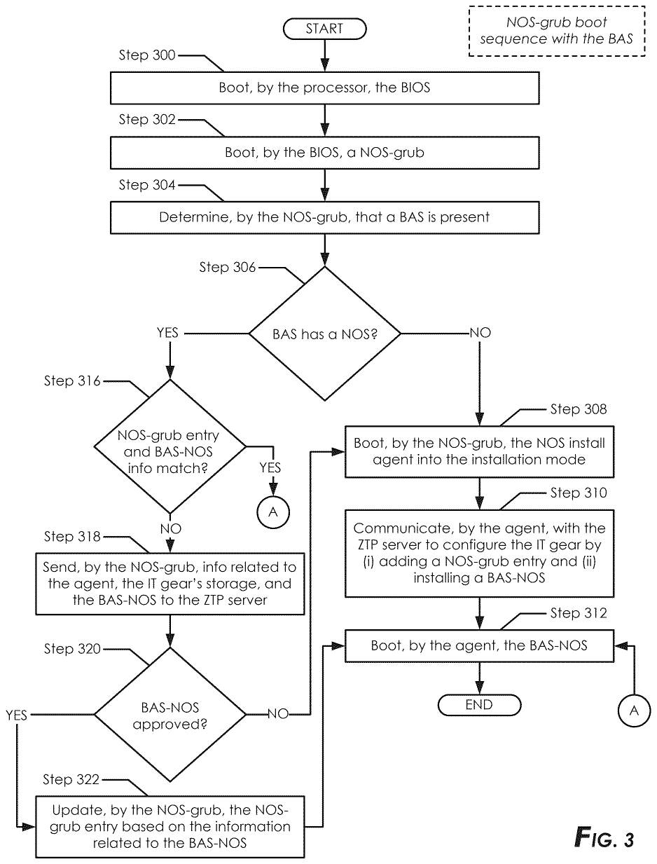

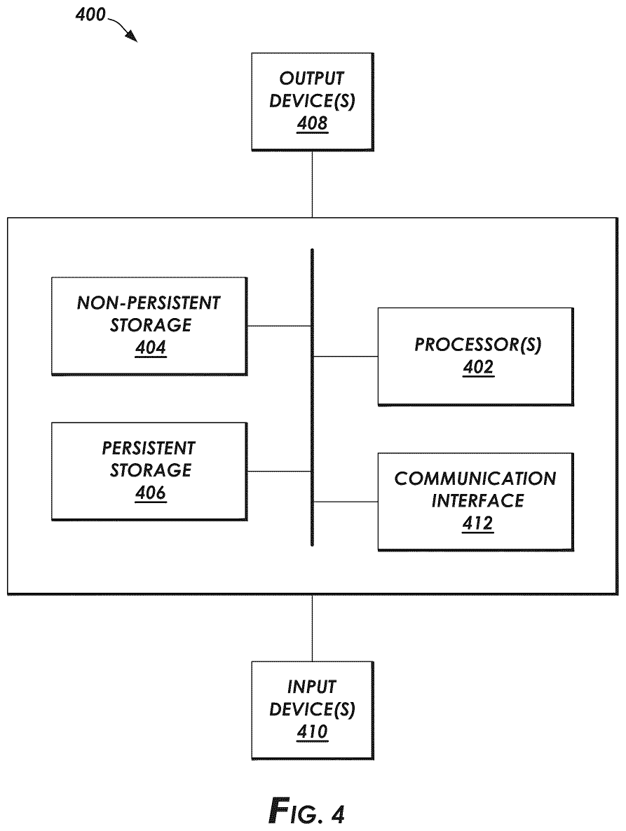

In one or more embodiments, the system (100) may be a distributed system (e.g., a data processing environment) and may deliver at least computing power (e.g., real-time (on the order of milliseconds (ms) or less) network monitoring, server virtualization, data deduplication, etc.), storage capacity (e.g., data backup), and data protection (e.g., software-defined data protection, disaster recovery, etc.) as a service to users (e.g., people, tenants, etc.) of clients (e.g., 110A, 110N, etc.). For example, the system (100) may be configured to organize unbounded, continuously generated data into a data stream. The system (100) may also represent a comprehensive middleware layer executing on computing devices (e.g., 400, FIG. 4) that supports application and storage environments.

In one or more embodiments, the system (100) may support one or more virtual machine (VM) environments, and may map capacity requirements (e.g., computational load, storage access, etc.) of VMs and supported applications to available resources (e.g., processing resources, storage resources, etc.) managed by the environments. Further, the system (100) may be configured for workload placement collaboration and computing resource (e.g., processing, storage/memory, virtualization, networking, etc.) exchange.

To provide computer-implemented services to the users, the system (100) may perform some computations (e.g., data collection, distributed processing of collected data, etc.) locally (e.g., at the users'site using the clients (e.g., 110A, 110N, etc.)) and other computations remotely (e.g., away from the users'site using the IHSs (e.g., 140A, 140N, etc.)) from the users. By doing so, the users may utilize different computing devices (e.g., 400, FIG. 4) that have different quantities of computing resources (e.g., processing cycles, memory, storage, etc.) while still being afforded consistent user experience. For example, by performing some computations remotely, the system (100) (i) may maintain the consistent user experience provided by different computing devices even when the different computing devices possess different quantities of computing resources, and (ii) may process data more efficiently in a distributed manner by avoiding the overhead associated with data distribution and/or command and control via separate connections.

As used herein, “computing” refers to any operations that may be performed by a computer, including (but not limited to): computation, data storage, data retrieval, communications, etc. Further, as used herein, a “computing device” refers to any device in which a computing operation may be carried out. A computing device may be, for example (but not limited to): a compute component, a storage component, a network device, a telecommunications component, etc.

As used herein, a “resource” refers to any program, application, document, file, asset, executable program file, desktop environment, computing environment, or other resource made available to, for example, a user/customer of a client (described below). The resource may be delivered to the client via, for example (but not limited to): conventional installation, a method for streaming, a VM executing on a remote computing device, execution from a removable storage device connected to the client (such as universal serial bus (USB) device), etc.

In one or more embodiments, a client (e.g., 110A, 110N, etc.) may include functionality to, e.g.,: (i) capture sensory input (e.g., sensor data) in the form of text, audio, video, touch or motion, (ii) collect massive amounts of data at the edge of an Internet of Things (IoT) network (where, the collected data may be grouped as: (a) data that needs no further action and does not need to be stored, (b) data that should be retained for later analysis and/or record keeping, and (c) data that requires an immediate action/response), (iii) provide to other entities (e.g., IHS A (140A)), store, or otherwise utilize captured sensor data (and/or any other type and/or quantity of data), (iv) provide surveillance services (e.g., determining object-level information, performing face recognition, etc.) for scenes (e.g., a physical region of space), (v) initiate artificial intelligence (AI) model training and/or AI inferencing applications on one or more IHSs (e.g., 140A, 140N, etc.), (vi) monitor the status of the AI model training and/or receive the results of AI inferencing applications, and/or (vii) permit users to interact with the network (130). One of ordinary skill will appreciate that the client may perform other functionalities without departing from the scope of the embodiments disclosed herein.

In one or more embodiments, the clients (e.g., 110A, 110N, etc.) may be geographically distributed devices (e.g., user devices, front-end devices, etc.) and may have relatively restricted hardware and/or software resources when compared to the IHSs (e.g., 140A, 140N, etc.). As being, for example, a sensing device, each of the clients may be adapted to provide monitoring services. For example, a client may monitor the state of a scene (e.g., objects disposed in a scene). The monitoring may be performed by obtaining sensor data from sensors that are adapted to obtain information regarding the scene, in which a client may include and/or be operatively coupled to one or more sensors (e.g., a physical device adapted to obtain information regarding one or more scenes).

In one or more embodiments, the sensor data may be any quantity and types of measurements (e.g., of a scene's properties, of an environment's properties, etc.) over any period(s) of time and/or at any points-in-time (e.g., any type of information obtained from one or more sensors, in which different portions of the sensor data may be associated with different periods of time (when the corresponding portions of sensor data were obtained)). The sensor data may be obtained using one or more sensors. The sensor may be, for example (but not limited to): a visual sensor (e.g., a camera adapted to obtain optical information (e.g., a pattern of light scattered off of the scene) regarding a scene/environment), an audio sensor (e.g., a microphone adapted to obtain auditory information (e.g., a pattern of sound from the scene) regarding a scene), an electromagnetic radiation sensor (e.g., an infrared sensor), a chemical detection sensor, a temperature sensor, a humidity sensor, a count sensor, a distance sensor, a global positioning system sensor, a biological sensor, a differential pressure sensor, a corrosion sensor, etc.

In one or more embodiments, the clients (e.g., 110A, 110N, etc.) may be physical or logical computing devices configured for hosting one or more workloads, or for providing a computing environment whereon workloads may be implemented. The clients may provide computing environments that are configured for, at least: (i) workload placement collaboration, (ii) computing resource (e.g., processing, storage/memory, virtualization, networking, etc.) exchange, and (iii) protecting workloads (including their applications and application data) of any size and scale (based on, for example, one or more service level agreements (SLAs) configured by users of the clients). The clients (e.g., 110A, 110N, etc.) may correspond to computing devices that one or more users use to interact with one or more components of the system (100).

In one or more embodiments, a client (e.g., 110A, 110N, etc.) may represent a physical appliance or a computing device operated by one or more individuals of (or employed by) an organization. Examples of said individual(s) may include, but not limited to, any organization executive(s) (e.g., chief executive officer (CEO), chief financial officer (CFO), etc.), and any employee(s) in the accounting/finance team of the organization (e.g., a collector person). Further, the organization may refer to any enterprise at least engaged in for-profit commercial, industrial, or professional activities.

In one or more embodiments, a client (e.g., 110A, 110N, etc.) may include any number of applications (and/or content accessible through the applications) that provide computer-implemented services to a user. Applications may be designed and configured to perform one or more functions instantiated by a user of the client. In order to provide application services, each application may host similar or different components. The components may be, for example (but not limited to): instances of databases, instances of email servers, etc. Applications may be executed on one or more clients as instances of the application.

Applications may vary in different embodiments, but in certain embodiments, applications may be custom developed or commercial (e.g., off-the-shelf) applications that a user desires to execute in a client (e.g., 110A, 110N, etc.). In one or more embodiments, applications may be logical entities executed using computing resources of a client. For example, applications may be implemented as computer instructions stored on persistent storage of the client that when executed by the processor(s) of the client, cause the client to provide the functionality of the applications described throughout the application.

In one or more embodiments, while performing, for example, one or more operations requested by a user, applications installed on a client (e.g., 110A, 110N, etc.) may include functionality to request and use physical and logical resources of the client. Applications may also include functionality to use data stored in storage/memory resources of the client. The applications may perform other types of functionalities not listed above without departing from the scope of the embodiments disclosed herein. While providing application services to a user, applications may store data that may be relevant to the user in storage/memory resources of the client.

In one or more embodiments, to provide services to the users, the clients (e.g., 110A, 110N, etc.) may utilize, rely on, or otherwise cooperate with the IHSs (e.g., 140A, 140N, etc.). For example, the clients may issue requests to IHS A (140A) to receive responses and interact with various components of IHS A (140A). The clients may also request data from and/or send data to IHS A (140A) (for example, the clients may transmit information to IHS A that allows IHS A to perform computations, the results of which are used by the clients to provide services to the users). As yet another example, the clients may utilize computer-implemented services provided by IHS N (140N). When the clients interact with IHS N (140N), data that is relevant to the clients may be stored (temporarily or permanently) in IHS N.

In one or more embodiments, a client (e.g., 110A, 110N, etc.) may be capable of, e.g.,: (i) collecting users'inputs, (ii) correlating collected users'inputs to the computer-implemented services to be provided to the users, (iii) communicating with the IHSs (e.g., 140A, 140N, etc.) that perform computations necessary to provide the computer-implemented services, (iv) using the computations performed by, for example, IHS A (140A) to provide the computer-implemented services in a manner that appears (to the users) to be performed locally to the users, and/or (v) communicating with any virtual desktop (VD) in a virtual desktop infrastructure (VDI) environment (or a virtualized architecture) provided by the IHSs (using any known protocol in the art), for example, to exchange remote desktop traffic or any other regular protocol traffic (so that, once authenticated, users may remotely access independent VDs).

As described above, the clients (e.g., 110A, 110N, etc.) may provide computer-implemented services to users (and/or other computing devices). The clients may provide any number and any type of computer-implemented services. To provide computer-implemented services, each client may include a collection of physical components (e.g., processing resources, storage/memory resources, networking resources, etc.) configured to perform operations of the client and/or otherwise execute a collection of logical components (e.g., virtualization resources) of the client.

In one or more embodiments, a processing resource (not shown) may refer to a measurable quantity of a processing-relevant resource type, which can be requested, allocated, and consumed. A processing-relevant resource type may encompass a physical device (i.e., hardware), a logical intelligence (i.e., software), or a combination thereof, which may provide processing or computing functionality and/or services. Examples of a processing-relevant resource type may include (but not limited to): a CPU, a graphics processing unit (GPU), a data processing unit (DPU), a computation acceleration resource, an ASIC, a digital signal processor for facilitating high speed communication, etc.

In one or more embodiments, a storage or memory resource (not shown) may refer to a measurable quantity of a storage/memory-relevant resource type, which can be requested, allocated, and consumed (for example, to store sensor data and provide previously stored data). A storage/memory-relevant resource type may encompass a physical device, a logical intelligence, or a combination thereof, which may provide temporary or permanent data storage functionality and/or services. Examples of a storage/memory-relevant resource type may be (but not limited to): a hard disk drive (HDD), an SSD, random-access memory (RAM), Flash memory, a tape drive, a fibre-channel (FC) based storage device, a floppy disk, a diskette, a compact disc (CD), a digital versatile disc (DVD), a non-volatile memory express (NVMe) device, a NVMe over Fabrics (NVMe-oF) device, resistive RAM (ReRAM), persistent memory (PMEM), virtualized storage, virtualized memory, etc.

In one or more embodiments, while the clients (e.g., 110A, 110N, etc.) provide computer-implemented services to users, the clients may store data that may be relevant to the users to the storage/memory resources. When the user-relevant data is stored (temporarily or permanently), the user-relevant data may be subjected to loss, inaccessibility, or other undesirable characteristics based on the operation of the storage/memory resources.

To mitigate, limit, and/or prevent such undesirable characteristics, users of the clients (e.g., 110A, 110N, etc.) may enter into agreements (e.g., SLAs) with providers (e.g., vendors) of the storage/memory resources. These agreements may limit the potential exposure of user-relevant data to undesirable characteristics. These agreements may, for example, require duplication of the user-relevant data to other locations so that if the storage/memory resources fail, another copy (or other data structure usable to recover the data on the storage/memory resources) of the user-relevant data may be obtained. These agreements may specify other types of activities to be performed with respect to the storage/memory resources without departing from the scope of the embodiments disclosed herein.

In one or more embodiments, a networking resource (not shown) may refer to a measurable quantity of a networking-relevant resource type, which can be requested, allocated, and consumed. A networking-relevant resource type may encompass a physical device, a logical intelligence, or a combination thereof, which may provide network connectivity functionality and/or services. Examples of a networking-relevant resource type may include (but not limited to): a network interface card (NIC), a network adapter, a network processor, etc.

In one or more embodiments, a networking resource may provide capabilities to interface a client with external entities (e.g., IHS A (140A)) and to allow for the transmission and receipt of data with those entities. A networking resource may communicate via any suitable form of wired interface (e.g., Ethernet, fiber optic, serial communication etc.) and/or wireless interface, and may utilize one or more protocols (e.g., transport control protocol (TCP), user datagram protocol (UDP), remote direct memory access (RDMA), RDMA over Converged Ethernet (RoCE), IEEE 801.11, etc.) for the transmission and receipt of data.

In one or more embodiments, a networking resource may implement and/or support the above-mentioned protocols to enable the communication between the client and the external entities. For example, a networking resource may enable the client to be operatively connected, via Ethernet, using a TCP protocol to form a “network fabric”, and may enable the communication of data between the client and the external entities. In one or more embodiments, each client may be given a unique identifier (e.g., an IP address) to be used when utilizing the above-mentioned protocols.

Further, a networking resource, when using a certain protocol or a variant thereof, may support streamlined access to storage/memory media of other clients (e.g., 110A, 110N, etc.). For example, when utilizing Remote DMA (“RDMA”), e.g., RoCE to access data on another client, it may not be necessary to interact with the logical components of that client. Rather, when using RDMA, it may be possible for the networking resource to interact with the physical components of that client to retrieve and/or transmit data, thereby avoiding any higher-level processing by the logical components executing on that client.

In one or more embodiments, a virtualization resource (not shown) may refer to a measurable quantity of a virtualization-relevant resource type (e.g., a virtual hardware component), which can be requested, allocated, and consumed, as a replacement for a physical hardware component. A virtualization-relevant resource type may encompass a physical device, a logical intelligence, or a combination thereof, which may provide computing abstraction functionality and/or services. Examples of a virtualization-relevant resource type may include (but not limited to): a virtual server, a VM, a container, a virtual CPU (vCPU), a virtual storage pool, etc.

In one or more embodiments, a virtualization resource may include a hypervisor (e.g., a VM monitor), in which the hypervisor may be configured to orchestrate an operation of, for example, a VM by allocating computing resources of a client (e.g., 110A, 110N, etc.) to the VM. In one or more embodiments, the hypervisor may be a physical device including circuitry. The physical device may be, for example (but not limited to): an FPGA, an application-specific integrated circuit, a programmable processor, a microcontroller, a digital signal processor, etc. The physical device may be adapted to provide the functionality of the hypervisor. Alternatively, in one or more of embodiments, the hypervisor may be implemented as computer instructions stored on storage/memory resources of the client that when executed by processing resources of the client, cause the client to provide the functionality of the hypervisor.

In one or more embodiments, a client (e.g., 110A, 110N, etc.) may be, for example (but not limited to): a physical computing device, a smartphone, a tablet, a wearable, a gadget, a closed-circuit television (CCTV) camera, a music player, a game controller, etc. Different clients may have different computational capabilities. In one or more embodiments, Client A (110A) may have 16 GB of DRAM and 1 CPU with 12 cores, whereas Client N (110N) may have 8 GB of PMEM and 1 CPU with 16 cores. Other different computational capabilities of the clients not listed above may also be considered without departing from the scope of the embodiments disclosed herein.

Further, in one or more embodiments, a client (e.g., 110A, 110N, etc.) may be implemented as a computing device (e.g., 400, FIG. 4). The computing device may be, for example, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the client described throughout the application.

Alternatively, in one or more embodiments, the client (e.g., 110A, 110N, etc.) may be implemented as a logical device (e.g., a VM). The logical device may utilize the computing resources of any number of computing devices to provide the functionality of the client described throughout this application.

In one or more embodiments, users (e.g., administrators, organization executives, etc.) may interact with (or operate) the clients (e.g., 110A, 110N, etc.) in order to perform work-related tasks (e.g., production workloads). In one or more embodiments, the accessibility of users to the clients may depend on a regulation set by an administrator of the clients. To this end, each user may have a personalized user account that may, for example, grant access to certain data, applications, and computing resources of the clients. This may be realized by implementing virtualization technology. In one or more embodiments, an administrator may be a user with permission (e.g., a user that has root-level access) to make changes to the clients that will affect other users of the clients.

In one or more embodiments, for example, a user may be automatically directed to a login screen of a client when the user connected to that client. Once the login screen of the client is displayed, the user may enter credentials (e.g., username, password, etc.) of the user on the login screen. The login screen may be a graphical user interface (GUI) generated by a visualization module (not shown) of the client. In one or more embodiments, the visualization module may be implemented in hardware (e.g., circuitry), software, or any combination thereof.

In one or more embodiments, a GUI may be displayed on a display of a computing device (e.g., 400, FIG. 4) using functionalities of a display engine (not shown), in which the display engine is operatively connected to the computing device. The display engine may be implemented using hardware (or a hardware component), software (or a software component), or any combination thereof. The login screen may be displayed in any visual format that would allow the user to easily comprehend (e.g., read and parse) the listed information.

In one or more embodiments, an IHS of the IHSs (e.g., 140A, 140N, etc.) may include functionality to, e.g.,: (i) obtain (or receive) data (e.g., any type and/or quantity of input) from any source (and, if necessary, aggregate the data); (ii) process/analyze data that is received from one or more clients (e.g., 110A, 110N, etc.) to generate additional data that is derived from the obtained data without experiencing any middleware and hardware limitations; (iii) provide meaningful information (e.g., a response) back to the corresponding clients; (iv) filter data (e.g., received from a client) before pushing the data (and/or the derived data) to the storage for management of the data and/or for storage of the data (while pushing the data, the IHS may include information regarding a source of the data (e.g., an identifier of the source) so that such information may be used to associate provided data with one or more of the users (or data owners)); (v) host and maintain various workloads; (vi) provide a computing environment whereon workloads may be implemented (e.g., employing linear, non-linear, and/or AI models to perform cloud-based data processing); (vii) incorporate strategies (e.g., strategies to provide VDI capabilities) for remotely enhancing capabilities of the clients; (viii) provide robust security features to the clients and make sure that a minimum level of service is always provided to a user of a client; (ix) transmit the result(s) of the computing work performed (e.g., real-time business insights, equipment maintenance predictions, other actionable responses, etc.) to another IHS for review and/or other human interactions; (x) exchange data with other devices registered in/to the network (130) in order to, for example, participate in a collaborative workload placement (e.g., the IHS may split up a request (e.g., an operation, a task, an activity, etc.) with another IHS, coordinating its efforts to complete the request more efficiently than if the IHS had been responsible for completing the request); (xi) provide software-defined data protection for the clients (e.g., 110A, 110N, etc.); (xii) provide automated data discovery, protection, management, and recovery operations for the clients; (xiii) monitor operational states of the clients; (xiv) regularly back up configuration information of the clients to a storage system (not shown); (xv) provide (e.g., via a broadcast, multicast, or unicast mechanism) information (e.g., a location identifier, the amount of available resources, etc.) associated with the IHS to other IHSs of the system (100); (xvi) configure or control any mechanism that defines when, how, and what data to provide to the clients and/or to the storage system; (xvii) provide data deduplication to the clients (in conjunction with the storage system); (xviii) orchestrate data protection through one or more GUIs; (xix) empower data owners (e.g., users of the clients) to perform self-service data backup and restore operations from their native applications; (xx) ensure compliance and satisfy different types of service level objectives (SLOs) set by an administrator/user; (xxi) increase resiliency of an organization by enabling rapid recovery or cloud disaster recovery from cyber incidents; (xxii) provide operational simplicity, agility, and flexibility for physical, virtual, and cloud-native environments; (xxiii) consolidate multiple data process or protection requests (received from, for example, clients) so that duplicative operations (which may not be useful for restoration purposes) are not generated; (xxiv) initiate multiple data process or protection operations in parallel (e.g., an IHS may host multiple operations, in which each of the multiple operations may (a) manage the initiation of a respective operation and (b) operate concurrently to initiate multiple operations); and/or (xxv) manage operations of one or more clients (e.g., receiving information from the clients regarding changes in the operation of the clients) to improve their operations (e.g., improve the quality of data being generated, decrease the computing resources cost of generating data, etc.). In one or more embodiments, in order to read, write, or store data, the IHS (e.g., 140A, 140N, etc.) may communicate with, for example, any storage device in the system (100).

In one or more embodiments, because technology and information handling needs vary between different users or applications, IHSs (e.g., 140A, 140N, etc.) may also vary regarding what information/data is handled, how the information is handled, how much information is processed, stored, or communicated, and how quickly and efficiently the information may be processed, stored, or communicated. The variations in IHSs may allow for the IHSs to be general or configured for a specific user or specific use such as financial transaction processing, airline reservations, enterprise data storage, or global communications. In addition, IHSs (e.g., 140A, 140N, etc.) may include a variety of hardware and software components that may be configured to process, store, and communicate information and may include one or more computer systems, data storage systems, and networking systems.

As described above, an IHS (e.g., 140A, 140N, etc.) may be capable of providing a range of functionalities/services to the users of the clients (e.g., 110A, 110N, etc.). However, not all users may be allowed to receive all the services. To manage the services provided to the users of the clients, a service manager (not shown) in accordance with embodiments disclosed herein may manage the operation of the network (130), in which the clients are operably connected to the IHSs over the network. Specifically, the service manager (i) may identify services to be provided by the IHSs (for example, based on the number of users using the clients) and (ii) may limit communications of the clients to receive IHS provided services.

For example, the priority (e.g., the user access level) of a user may be used to determine how to manage computing resources of IHS A (140A) to provide services to that user. As yet another example, the priority of a user may be used to identify the services that need to be provided to that user. As yet another example, the priority of a user may be used to determine how quickly communications (for the purposes of providing services in cooperation with the internal network (and its subcomponents)) are to be processed by the internal network.

Further, consider a scenario where a first user is to be treated as a normal user (e.g. a non-privileged user, a user with a user access level/tier of 4/10). In such a scenario, the user level of that user may indicate that certain ports (of the subcomponents of the network corresponding to communication protocols such as the TCP, the UDP, etc.) are to be opened, other ports are to be blocked/disabled so that (i) certain services are to be provided to the user by IHS N (140N) (e.g., while the computing resources of IHS N may be capable of providing/performing any number of remote computer-implemented services, they may be limited in providing some of the services over the network enabled/provided by the network (130)) and (ii) network traffic from that user is to be afforded a normal level of quality (e.g., a normal processing rate with a limited communication bandwidth (BW)). By doing so, (i) computer-implemented services provided to the users of the clients (e.g., 110A, 110N, etc.) may be granularly configured without modifying the operation(s) of the clients and (ii) the overhead for managing the services of the clients may be reduced by not requiring modification of the operation(s) of the clients directly.

In contrast, a second user may be determined to be a high priority user (e.g., a privileged user, a user with a user access level of 9/10). In such a case, the user level of that user may indicate that more ports are to be opened than were for the first user so that (i) IHS A (140A) may provide more services to the second user and (ii) network traffic from that user is to be afforded a high-level of quality (e.g., a higher processing rate than the traffic from the normal user).

As used herein, a “workload” is a physical or logical component configured to perform certain work functions. Workloads may be instantiated and operated while consuming computing resources allocated thereto. A user may configure a data protection policy for various workload types. Examples of a workload may include (but not limited to): an AI workload, a data protection workload, a VM, a container, a network-attached storage (NAS), a database, an application, a collection of microservices, a file system (FS), small workloads with lower priority workloads (e.g., FS host data, operating system (OS) data, etc.), medium workloads with higher priority (e.g., VM with FS data, network data management protocol (NDMP) data, etc.), large workloads with critical priority (e.g., mission critical application data), etc.

As used herein, a “policy” is a collection of information, such as a backup policy or other data protection policy, that includes, for example (but not limited to): identity of source data that is to be protected, backup schedule and retention requirements for backed up source data, identity of an SLA (or a rule) that applies to source data, identity of a target device where source data is to be stored, etc.

As used herein, the term “backup” is intended to be broad in scope. In this manner, example backups (in connection with which embodiments disclosed herein) may be employed include (but not limited to): full backups, partial backups, clones, snapshots, incremental backups, differential backups, etc.

As used herein, “data retention” is a period of time, with a definite start and end, within which the data should be retained in a storage device/system. For example, a set of user requirements and/or technical considerations (e.g., security considerations, performance considerations, etc.) of a data center may be used to generate a data retention policy specifying that user data should be retained in the database for seven years.

As used herein, a “rule” is a guideline used by an SLA component to select a particular target device (or target devices), based on the ability of the target device to meet requirements imposed by the SLA. For example, a rule may specify that an HDD having a particular performance parameter should be used as the target device. A target device selected by the SLA component may be identified as part of a backup policy or other data protection policy.

Further, while a single IHS (e.g., 140A) is considered above, the term “IHS” includes any collection of systems or sub-systems that individually or jointly execute a set, or multiple sets, of instructions to provide one or more computer-implemented services. For example, a single IHS may provide a computer-implemented service on its own (i.e., independently) while other IHSs may provide a second computer-implemented service cooperatively (e.g., each of the other IHSs may provide similar or different services that form the cooperatively provided service).

As described above, an IHS (e.g., 140A) may provide any quantity and any type of computer-implemented services. To provide computer-implemented services, the IHS may be a heterogeneous set, including a collection of physical components/resources (discussed above) configured to perform operations of the IHS and/or otherwise execute a collection of logical components/resources (discussed above) of the IHS.

In one or more embodiments, an IHS (e.g., 140A, 140N, etc.) may implement a management model to manage the aforementioned computing resources in a particular manner. The management model may give rise to additional functionalities for the computing resources. For example, the management model may automatically store multiple copies of data in multiple locations when a single write of the data is received. By doing so, a loss of a single copy of the data may not result in a complete loss of the data. Other management models may include, for example, adding additional information to stored data to improve its ability to be recovered, methods of communicating with other devices to improve the likelihood of receiving the communications, etc. Any type and number of management models may be implemented to provide additional functionalities using the computing resources without departing from the scope of the embodiments disclosed herein.

One of ordinary skill will appreciate that an IHS (e.g., 140A, 140N, etc.) may perform other functionalities without departing from the scope of the embodiments disclosed herein.

In one or more embodiments, an IHS (e.g., 140A, 140N, etc.) may be implemented as a computing device (e.g., 400, FIG. 4). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the IHS described throughout the application.

Alternatively, in one or more embodiments, similar to a client (e.g., 110A, 110N, etc.), the IHS may also be implemented as a logical device.

Turning now to the vendor/manufacturer (125), as being a trusted facility/site, the vendor (125) may be part of a supply chain route (that may be traversed by an enterprise product (e.g., an ITC (e.g., 175, FIG. 1.7) such as a network switch), in which the supply chain route may outline a sequence of trusted sites through which the enterprise product transitions during its lifetime.

In one or more embodiments, the vendor (125) may reference a trusted facility where a supplier of an enterprise product (e.g., a physical product such as an ITC, a logical product such as a software program, etc.) may manufacture the enterprise product in part or in entirety. Manufacturing of an enterprise product may include one or more steps/stages, for example (but not limited to): steps of a developer/administrator flow of an ITC; steps of generating an ownership voucher (OV) (based on the credentials specified in device initialization (DI) process/protocol (where the OV may not be stored in the corresponding ITC; instead, the OV may be transmitted along the supply chain route to mirror the ITC's progress); steps of initial provisioning of the ITC; steps of generating a public and private key pair for the ITC (before shipping the ITC to a user/customer), where the public key of the key pair is embedded into a corresponding OV; manufacturing of chassis and front panel parts (of the ITC); subassembly of chassis parts to obtain a chassis; integration of a chassis and front panel parts to obtain a chassis enclosure; procurement of a power supply and/or cables and/or a backplane; integration of a power supply and/or cables and/or a backplane into a chassis enclosure; procurement of a baseboard and integration thereof into a chassis enclosure; procurement of one or more expansion cards and integration thereof into a chassis enclosure; procurement of one or more storage devices and integration thereof into a chassis enclosure; procurement of parts such as computer processors (e.g., CPUs, DPUs, etc.) as well as computer memory and integration thereof into a chassis enclosure to obtain a fully-assembled enterprise product; installation of an OS, zero or more software applications, and/or firmware onto a fully-assembled enterprise product to obtain a fully-integrated enterprise product; etc.

In one or more embodiments, the aforementioned enterprise product manufacturing steps may be performed across one or more vendors. Further, the vendor (125) may include functionality to service (e.g., providing technical support for installation anomalies such as providing recommendations (e.g., remediation steps) and/or fixes for hardware and/or software failures), upgrade, troubleshoot, test, package, and/or distribute various different enterprise products. One of ordinary skill will appreciate that the vendor (125) may perform other functionalities without departing from the scope of the embodiments disclosed herein.

Referring to FIG. 1.1, the ZTP server (120) is demonstrated as a standalone computing device/entity; however, embodiments disclosed herein are not limited as such. The ZTP server (120) may be demonstrated as part of the vendor (125) (e.g., as deployed to the vendor (125)).

As used herein, ZTP (or automatic provisioning) of an ITC (e.g., an IT gear, a customer premises equipment, a storage device, etc.) may help to (i) eliminate the need for an administrator (e.g., a technical support member) to visit a user/installation site to provision/configure the ITC, (ii) avoid reshipment of ITCs to the installation site, and/or (iii) optimize use of resources for computing device provisioning purposes.

In one or more embodiments, as being a physical computing device or a logical computing device, the ZTP server (120) (e.g., an authorized provisioning server/manager) may include functionality to, at least: (i) perform ZTP of ITCs (e.g., network switches, network devices, network routers, etc.) and inventory management of those ITCs; (ii) receive a request (e.g., a configuration/authorization request) from a NOS install agent (or a NOS installation agent, see FIG. 1.11) to authorize/approve, for example, a BAS-NOS (see FIG. 1.11), (iii) upon receipt of the request (along with additional data (such as information related to the NOS install agent, information related to the BAS-NOS, etc.)), make a determination that the BAS-NOS is approved (or not approved); and/or (iv) implement various ITC provisioning mechanisms to ensure newly installed, updated, or replaced/refreshed ITC, as well as any other network elements supporting ITC's access to the network (130), are appropriately provisioned to enable the ITC to perform its functionalities.

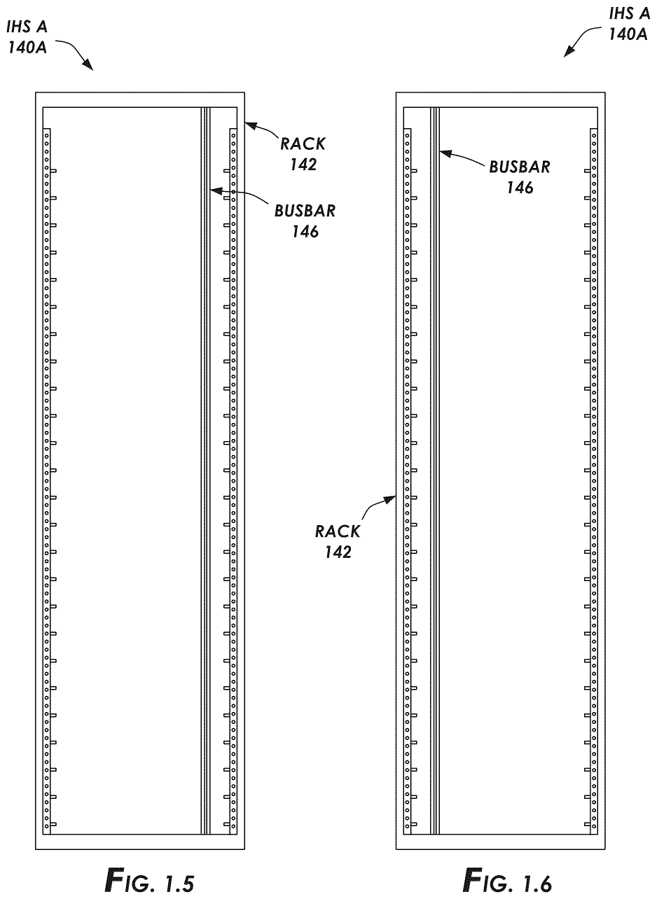

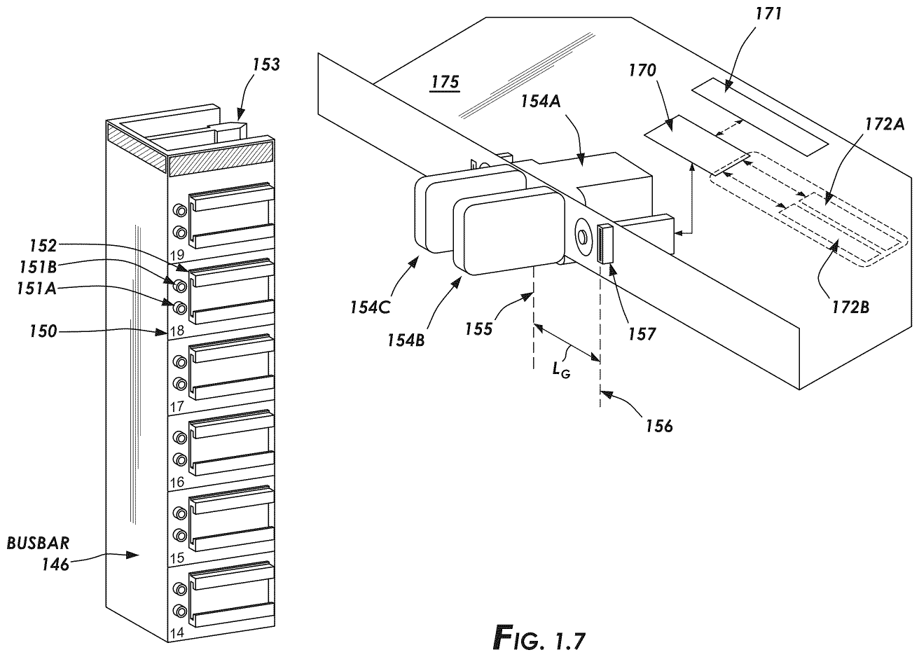

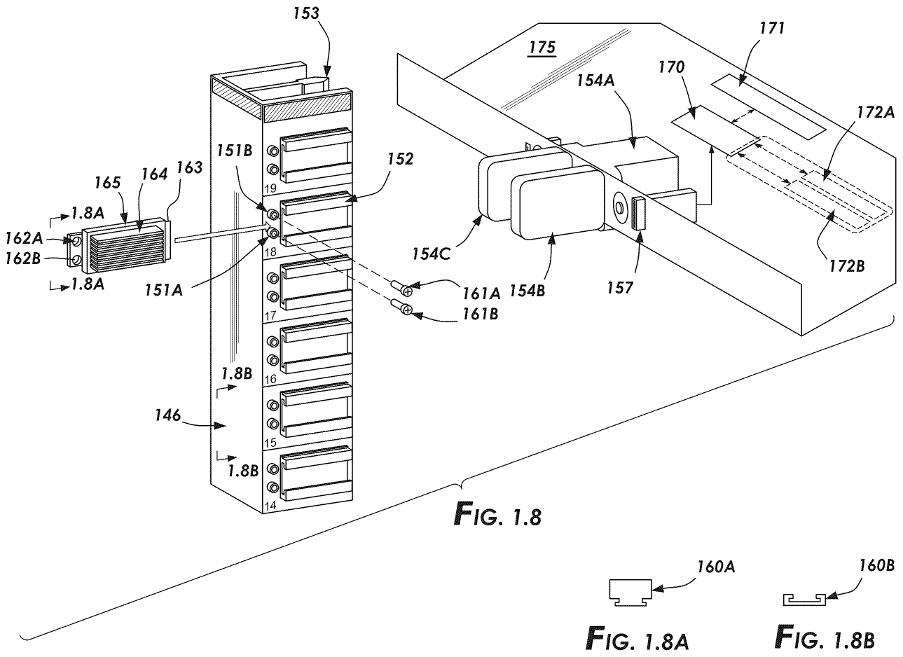

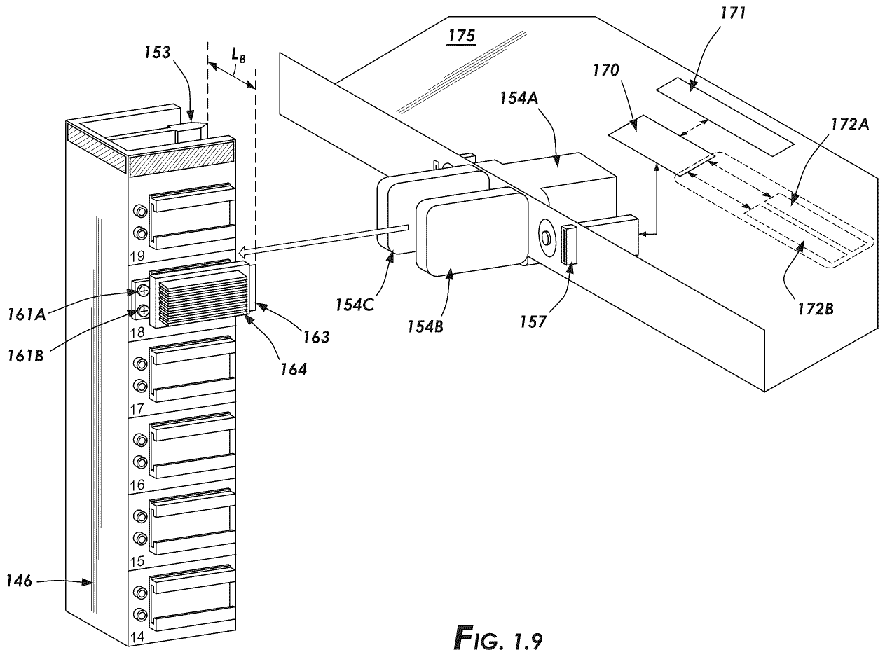

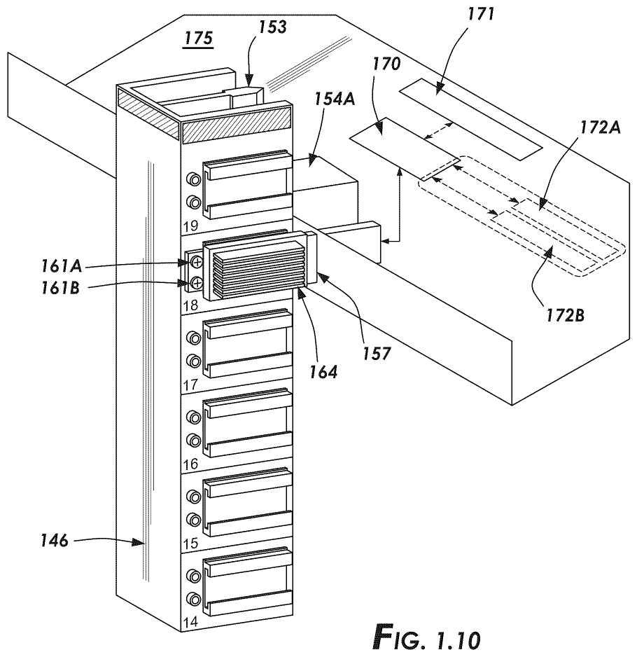

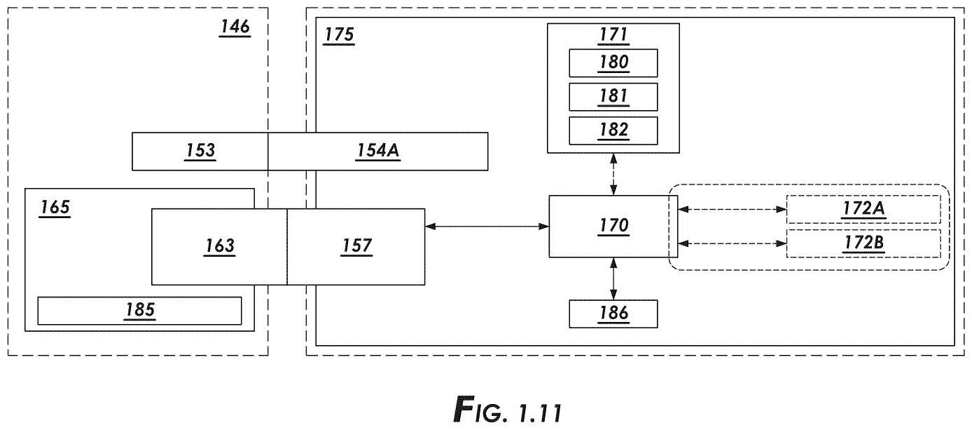

One of ordinary skill will appreciate that the ZTP server (120) may perform other functionalities without departing from the scope of the embodiments disclosed herein. In one or more embodiments, the ZTP server (120) may be configured to perform all, or a portion, of the functionalities described in FIGS. 2-3. The ZTP server (120) may be implemented as a computing device (e.g., 400, FIG. 4) using hardware (e.g., any number of integrated circuits for processing computer readable instructions, implemented on a corresponding entity's GPU(s), etc.), software (e.g., a computer program), or any combination thereof.

In one or more embodiments, all, or a portion, of the components of the system (100) may be operably connected each other and/or other entities via any combination of wired and/or wireless connections. For example, the aforementioned components may be operably connected, at least in part, via the network (130). Further, all, or a portion, of the components of the system (100) may interact with one another using any combination of wired and/or wireless communication protocols.

In one or more embodiments, the network (130) may represent a (decentralized or distributed) computing network and/or fabric configured for computing resource and/or messages exchange among registered computing devices (e.g., the clients, the IHSs, etc.). As discussed above, components of the system (100) may operatively connect to one another through the network (e.g., a storage area network (SAN), a personal area network (PAN), a LAN, a metropolitan area network (MAN), a WAN, a mobile network, a wireless LAN (WLAN), a virtual private network (VPN), an intranet, the Internet, etc.), which facilitates the communication of signals, data, and/or messages. In one or more embodiments, the network (130) may be implemented using any combination of wired and/or wireless network topologies, and the network may be operably connected to the Internet or other networks. Further, the network (130) may enable interactions between, for example, the clients and the IHSs through any number and type of wired and/or wireless network protocols (e.g., TCP, UDP, IPv4, etc.).

The network (130) may encompass various interconnected, network-enabled subcomponents (not shown) (e.g., switches, routers, gateways, cables etc.) that may facilitate communications between the components of the system (100). In one or more embodiments, the network-enabled subcomponents may be capable of: (i) performing one or more communication schemes (e.g., IP communications, Ethernet communications, etc.), (ii) being configured by one or more components in the network, and (iii) limiting communication(s) on a granular level (e.g., on a per-port level, on a per-sending device level, etc.). The network (130) and its subcomponents may be implemented using hardware, software, or any combination thereof.

In one or more embodiments, before communicating data over the network (130), the data may first be broken into smaller batches (e.g., data packets) so that larger size data can be communicated efficiently. For this reason, the network-enabled subcomponents may break data into data packets. The network-enabled subcomponents may then route each data packet in the network (130) to distribute network traffic uniformly.

In one or more embodiments, the network-enabled subcomponents may decide how real-time (e.g., on the order of ms or less) network traffic and non-real-time network traffic should be managed in the network (130). In one or more embodiments, the real-time network traffic may be high-priority (e.g., urgent, immediate, etc.) network traffic. For this reason, data packets of the real-time network traffic may need to be prioritized in the network (130). The real-time network traffic may include data packets related to, for example (but not limited to): videoconferencing, web browsing, voice over Internet Protocol (VoIP), etc.

While FIG. 1.1 shows a configuration of components, other system configurations may be used without departing from the scope of the embodiments disclosed herein.

Turning now to FIG. 1.2, FIG. 1.2 shows a diagram of an IHS (e.g., IHS A (140A)) (from an isometric view) in accordance with one or more embodiments disclosed herein. In one or more embodiments, IHS A (140A) may include a rack (142) and any number of computing devices (e.g., 144).

In one or more embodiments, the rack (142) may be a chassis (e.g., a mechanical structure, an ORV3 rack, etc.) that is configured to house/host one or more computing devices (or blades) (e.g., 144) and their components, to be positioned with respect to one another. For example, the rack (142) may be a mountable enclosure that enables the computing devices (e.g., 144) to be disposed within the rack (142). The rack (142) may be implemented as other types of structures adapted to host, position, orient, and/or otherwise physically, mechanically, electrically, and/or thermally manage the computing devices (e.g., 144). By managing the computing devices, the rack (142) may enable the computing devices to be densely packed in a space without negatively impacting the operation of IHS A (140A).

In one or more embodiments, a computing device (e.g., 144) may be a mechanical structure for housing hardware components of IHS A (140A). For example, the computing device (e.g., 144) may be implemented as a rack mountable enclosure for housing components of IHS A (140A). The computing device (e.g., 144) may be adapted to be disposed within the rack (142), and/or utilize services provided by the rack (142) and/or other components available in the system (e.g., 100, FIG. 1.1).

In one or more embodiments, the computing device (e.g., 144) may have any instrumentality or aggregate of instrumentalities operable to compute, classify, process, transmit, receive, retrieve, originate, switch, store, display, manifest, detect, record, reproduce, handle, and/or utilize any form of data for business, management, entertainment, or other purposes. Additional details of the computing device are described below in reference to FIG. 4.

In one or more embodiments, one or more isolators (not shown) may be attached to the rack (142) to make sure that, at least, the computing devices (e.g., 144) are ready-to-use when they deployed to the customer's site. For example, each isolator may provide shock isolation to components of a computing device such that the components may be protected from any damage (e.g., a vibrational damage).

Turning now to FIG. 1.3, FIG. 1.3 shows a diagram of the rack (142) (from a front view, without the computing devices) in accordance with one or more embodiments disclosed herein. Referring to FIG. 1.3, a busbar (146) is operatively connected (e.g., affixed, mounted, welded, glued, etc.) “vertically” to a rear side of the rack (142). Further, referring to FIG. 1.3, depending on a customer's deployment preference, the busbar (146) may be located/deployed at the center of the rear side of the rack (142).

In one or more embodiments, (i) the busbar (146) may be a silver plated conductor (e.g., a thick strip/bar of copper or aluminum) to ensure the connection/mating quality, (ii) the edge/tip of the busbar (or busbar interfaces) may be free of burrs, (iii) the depth of the busbar (146) may remain inside of the rack (142), (iv) the electrically conductive surface of the busbar (146) may have a continuous electrically conductive path to the frame of the rack (142), (v) the busbar (146) may be a 48 volts (V) busbar or a 54V busbar, (vi) the structure/geometry of the busbar (146) that provides/distributes electric power (e.g., from a power source via standardized cable connections such as power cables/whips) to an ITC (and/or other hardware components deployed inside or outside of the rack (142)) may have standardized interfaces between the rack (142) and the busbar (146) to allow for interoperability between the components, (vii) the busbar (146) may be a rack busbar that is designed for data center server racks (which is compliant with Open Compute Project (OCP) specifications), (viii) the busbar (146) may be interoperable with different ratings of busbar connectors, and/or (ix) the busbar (146) may have a “U-shaped” cross-section with opposing side walls (see e.g., FIG. 1.7). Additional details of the busbar are described below in reference to FIG. 1.7-1.11.

As used herein, a “cable” may be any cable, conduit, or line that carries one or more conductors and that is flexible over at least a portion of its length. A cable may include a connector portion, such as a plug, at one or more of its ends.

Turning now to FIG. 1.4, FIG. 1.4 shows a diagram of the rack (142) (from an isometric view, without the computing devices) in accordance with one or more embodiments disclosed herein.

Turning now to FIG. 1.5, FIG. 1.5 shows a diagram of the rack (142) (from a front view, without the computing devices) in accordance with one or more embodiments disclosed herein. Referring to FIG. 1.5, depending on a customer's deployment preference, the busbar (146) may be located close to the right of the rear side of the rack (142).

Turning now to FIG. 1.6, FIG. 1.6 shows a diagram of the rack (142) (from a front view, without the computing devices) in accordance with one or more embodiments disclosed herein. Referring to FIG. 1.6, depending on a customer's deployment preference, the busbar (146) may be located close to the left of the rear side of the rack (142).

Turning now to FIG. 1.7, FIG. 1.7 shows (a) a diagram of the busbar (146) (from an isometric view) and (b) a diagram of an ITC (175) (from an isometric view) in accordance with one or more embodiments disclosed herein.

In one or more embodiments, as being a physical hardware component, the busbar (146) includes/hosts, at least: (a) a busbar tip (153) and (b), for each computing device (e.g., 144, FIG. 1.2) (or RU section (e.g., 150), such as 14, 15, etc.) that is deployed to the rack (e.g., 142, FIG. 1.2), (i) a rail (e.g., 152), such as a C type DIN rail, (which is affixed/attached to the middle of a particular (right or left) side (or both sides) of the busbar (146)) and (ii) a set of mechanical connection components (e.g., 151A, 151B, etc.) such as a set of threaded inserts, which is placed close to a related rail (e.g., 152).

Those skilled in the art will appreciate that while each RU (or RU section on the busbar (146)) is shown as hosting a rail and a set of threaded inserts, a rail and a set of threaded inserts may not be present on each RU section (only a few RU sections may have these components, where ITCs are typically installed) without departing from the scope of the embodiments disclosed herein.

As a unit of measurement, the RU is equal to 1.75 inches and the RU defines an increment within a standard rack.

In one or more embodiments, as being a computing device, the ITC (175) includes a processor (170), a first storage/memory resource (171), a second storage/memory resource (172A), a third storage/memory resource (172B) (where the second storage/memory resource (172A) and the third storage/memory resource (172B) may be optional (as illustrated with dashed lines) to be used to storage, for example, telemetry data (e.g., system logs, application logs, etc.) obtained from a client (e.g., 110A, FIG. 1.1)), a basic input/output system (BIOS) (e.g., 186, FIG. 1.11), a connection mechanism (154A) that includes two connectors (154B-C), and a vertically aligned socket connector (157) (e.g., an M.2 connector (or an M.2 socket connector)). The ITC (175) may include additional, fewer, and/or different components without departing from the scope of the embodiments disclosed herein. Each component may be operably connected to any of the other component via any combination of wired and/or wireless connections.

In one or more embodiments, the processor (170) (e.g., an ITC processor, one or more processor cores, one or more processor micro-cores, etc.) may be communicatively coupled to the first storage/memory resource (171) (e.g., an SSD, an eMMC, etc.), the second storage/memory resource (172A), the third storage/memory resource (172B), the BIOS (e.g., 186, FIG. 1.11), and the socket connector (157) via any suitable interface, for example, a system interconnect including one or more system buses (operable to transmit communication between various hardware components) and/or peripheral component interconnect express (PCIe) bus/interface. In one or more embodiments, the processor (170) may be configured for executing machine-executable code like a CPU, a programmable logic array (PLA), an embedded device such as a System-on-a-Chip (SoC), or hardware/software control logic.

More specifically, the processor (170) may include any system, device, or apparatus configured to interpret and/or execute program instructions and/or process data, and may include, without limitation, a microprocessor, a microcontroller, a digital signal processor (DSP), an ASIC, or any other digital or analog circuitry configured to interpret and/or execute program instructions and/or process data. In one or more embodiments, the processor (170) may interpret and/or execute program instructions and/or process data stored in the first storage/memory resource (171) and/or another component of the ITC (e.g., 172A, 172B, etc.). Additionally, the processor (170) may manage operation of hardware devices of the ITC (175) in accordance with one or more models including, for example, data protection models, security models such as encrypting stored data, workload performance availability models such as implementing statistic characterization of workload performance, reporting models, etc.

While the processor (170) has been illustrated and described as including a limited number of specific components, the processor (170) may include additional, fewer, and/or different components without departing from the scope of the embodiments disclosed herein.

One of ordinary skill will appreciate that the processor (170) may perform other functionalities without departing from the scope of the embodiments disclosed herein. The processor (170) may be implemented using hardware (e.g., a physical device including circuitry), software, or any combination thereof.

In one or more embodiments, when two or more components are referred to as “coupled” to one another, such term indicates that such two or more components are in electronic communication or mechanical communication, as applicable, whether connected directly or indirectly, with or without intervening components.

In one or more embodiments, the first storage/memory resource (171) may have or provide at least the functionalities and/or characteristics of the storage or memory resources described above in reference to FIG. 1.1. The first storage/memory resource (171) may include any instrumentality or aggregation of instrumentalities that may retain data, program instructions, applications, and/or firmware (temporarily or permanently). In one or more embodiments, software and/or firmware stored within the first storage/memory resource (171) may be loaded into the processor (170) and executed during operation of the ITC (175).

Further, the first storage/memory resource (171) may include, without limitation, (i) storage media such as a direct access storage device (e.g., an HDD, an SSD, etc.), a sequential access storage device (e.g., a tape disk drive), compact disk, CD-ROM, RAM, DRAM, read-only memory (ROM), electrically erasable programmable read-only memory (EEPROM), magnetic storage, opto-magnetic storage, and/or volatile or nonvolatile memory (e.g., Flash memory) that retains data after power to the ITC (175) is turned off; (ii) communications media such as wires, optical fibers, microwaves, radio waves, and other electromagnetic and/or optical carriers; and/or any combination of thereof.

In one or more embodiments, the firmware stored in the first storage/memory resource (171) may include power profile data and thermal profile data for certain hardware devices (e.g., the processor (170), the BIOS (e.g., 186, FIG. 1.11), input/output controllers, etc.). Further, the first storage/memory resource (171) may include a unified extensible firmware interface (UEFI) (not shown) for accessing the BIOS (e.g., 186, FIG. 1.11) as well as updating the BIOS. In most cases, the UEFI may provide a software interface between the processor (170) and the BIOS (e.g., 186, FIG. 1.11), and may support remote diagnostics and repair of hardware devices.

While the first storage/memory resource (171) has been illustrated and described as including a limited number and type of data, the first storage/memory resource (171) may store additional, less, and/or different data without departing from the scope of the embodiments disclosed herein.

One of ordinary skill will appreciate that the first storage/memory resource (171) may perform other functionalities without departing from the scope of the embodiments disclosed herein. The first storage/memory resource (171) may be implemented using hardware, software, or any combination thereof.

In one or more embodiments, each of the second storage/memory resource (172A) and the third storage/memory resource (173A) may have or provide at least the functionalities and/or characteristics of the first storage/memory resource (171) described above.

In one or more embodiments, the BIOS (e.g., 186, FIG. 1.11) may refer to any system, device, or apparatus configured to (i) identify, test, and/or initialize resources (e.g., hardware components) of the ITC (175) (typically during boot up or power on of the ITC (175)), and/or initialize interoperation of the ITC (175) with other ITCs, and (ii) load a boot loader. The BIOS (e.g., 186, FIG. 1.11) may be implemented as a program of instructions (e.g., firmware, a firmware image, etc.) that may be read by and executed on the processor (170) to perform the functionalities of the BIOS (e.g., 186, FIG. 1.11).

In one or more embodiments, the BIOS (e.g., 186, FIG. 1.11) may include boot firmware configured to be the first code executed by the processor (170) when the ITC (175) is booted and/or powered on. As part of its initialization functionality, the boot firmware may be configured to set hardware components of the ITC (175) into a known state, so that one or more applications stored in, for example, the first storage/memory resource (171) may be executed by the processor (170) to provide computer-implemented services to one or more users of a client (e.g., 110A, FIG. 1.1). Further, the BIOS (e.g., 186, FIG. 1.11) may provide an abstraction layer for some of the hardware components of the ITC (175), as a consistent way for applications to interact with input/output components.

One of ordinary skill will appreciate that the BIOS (e.g., 186, FIG. 1.11) may perform other functionalities without departing from the scope of the embodiments disclosed herein. The BIOS (e.g., 186, FIG. 1.11) may be implemented using hardware, software, or any combination thereof.

Additional details of the ITC are described below in reference to FIG. 1.11.

Referring to FIG. 1.7, the distance (L_{G}, as illustrated as the distance between 155 and 156) between the socket connector (157) and the middle point between the connectors (154B-C) is fixed.

Turning now to FIG. 1.8, FIG. 1.8 shows (a) a diagram of the busbar (146) (from an isometric view) and (b) a diagram of the ITC (175) (from an isometric view) in accordance with one or more embodiments disclosed herein.

In one or more embodiments, as being a computing device, the ITC (175) includes the processor (170), the first storage/memory resource (171), the second storage/memory resource (172A), the third storage/memory resource (172B), the BIOS (e.g., 186, FIG. 1.11), the connection mechanism (154A) that includes two connectors (154B-C), and the socket connector (157). The aforementioned components may have the same or substantially the same functionality as the liked named components in FIG. 1.7.

In one or more embodiments, as being a physical hardware component, the busbar (146) hosts, at least: (a) the busbar tip (153) and (b), for each computing device (e.g., 144, FIG. 1.2) (or RU section (e.g., 150), such as 14, 15, etc.) that is deployed to the rack (e.g., 142, FIG. 1.2), (i) a rail (e.g., 152) and (ii) a set of mechanical connection components (e.g., 151A, 151B, etc.) such as a set of threaded inserts, which is placed close to a related rail (e.g., 152). Referring to FIG. 1.8, a user/customer may slide (indicated with a horizontal arrow) an enclosure (165) (e.g., a three-dimensional (3D) printed protective enclosure, a parent chassis, etc.) (that hosts a storage device (e.g., 185, FIG. 1.11)) along the rail (152) to position the enclosure (165) at a location on the busbar (146).

In one or more embodiments, the enclosure (165) may further host (a) a set of through threaded holes (e.g., 162A, 162B, etc.) and (b) a connector (163) (e.g., an M.2 connector), and a heat sink/exchanger (164) may be affixed (optionally) to the enclosure (165) via standard mechanical mechanisms (e.g., bolts, screws, nuts, studs, etc.). Other mechanical or non-mechanical (e.g., glue, an adhesive tape, etc.) mechanisms for affixing the heat sink (164) to the enclosure (165) may be used without departing from the scope of the embodiments disclosed herein.

Further, in order to affix/mount/slide the enclosure (165) to the rail (162) (or to the busbar (146)) firmly and to provide structural support/stability to hardware components (e.g., 185, 164, 163, etc.) hosted by the enclosure (165), (i) a first shape (e.g., a cross-section) (160B, see FIG. 1.8B) of the rail (162) enables the enclosure (165) to firmly slide along the rail (162) and (ii) the first shape (160B) matches with a second shape (e.g., a cross-section) (160A, see FIG. 1.8A) of the enclosure (165).

Once/After the enclosure (165) is positioned to the busbar (146), the user may mount a set of mechanical connection components (e.g., 161A, 161B, etc.) (such as bolts, screws, nuts, studs, etc.) to the set of threaded inserts (e.g., 151A, 151B, etc.) to fasten/affix the enclosure to the busbar (146), in which the set of mechanical connection components (e.g., 161A, 161B, etc.) passes through the through threaded holes (e.g., 162A, 162B, etc.).

In one or more embodiments, the heat sink (164) may provide a temperature management (e.g., cooling, heat dissipation, etc.) (through its fins) to the storage device (e.g., 185, FIG. 1.11), at least, when the NOS (or the BAS-NOS) is booted up (see Step 208 of FIG. 2). Those skilled in the art will appreciate that while the heat sink (164) is used to provide a temperature management to the enclosure (and its components), any other form of cooling (e.g., direct liquid cooling, using a liquid such as distilled water, glycol, etc.) may be used to provide a temperature management to the enclosure (and its components) without departing from the scope of the embodiments disclosed herein.

Turning now to FIG. 1.9, FIG. 1.9 shows (a) a diagram of the busbar (146) (from an isometric view) and (b) a diagram of the ITC (175) (from an isometric view) in accordance with one or more embodiments disclosed herein. As indicated in FIG. 1.9, (i) the enclosure (e.g., 165, FIG. 1.8) is fastened to the busbar (146) (where the connector (163) and the busbar tip (153) are at the same distance from the ITC (175)) and (ii) the enclosure does not protrude beyond the busbar (146).

In one or more embodiments, as being a computing device, the ITC (175) includes the processor (170), the first storage/memory resource (171), the second storage/memory resource (172A), the third storage/memory resource (172B), the BIOS (e.g., 186, FIG. 1.11), the connection mechanism (154A) that includes two connectors (154B-C), and the socket connector (157). The aforementioned components may have the same or substantially the same functionality as the liked named components in FIG. 1.7.

Referring to FIG. 1.9, the user pushes the ITC (175) (indicated with a horizontal arrow) to affix/mate/fasten the ITC (175) to the busbar (146). Further, to enable an easy and precise fastening process, the distance (L_{G}) (refer to FIG. 1.7) is equal to the distance (L_{B}) between the connector (163) and the busbar tip (153).

Turning now to FIG. 1.10, FIG. 1.10 shows (a) a diagram of the busbar (146) (from an isometric view) and (b) a diagram of the ITC (175) (from an isometric view) in accordance with one or more embodiments disclosed herein. As indicated in FIG. 1.10, (i) the ITC (175) is fastened to/plugged into the busbar (146), (ii) the connector (e.g., 163, FIG. 1.9) is operatively connected to (or mated with) the socket connector (157) (in order to, at least, enable a data exchange between the storage device (e.g., 185, FIG. 1.11) and the NOS-grub (e.g., 182, FIG. 1.11) (and/or the processor (170)) of the ITC (175)), and (iii) the two connectors (154B-C) of the connection mechanism (154A) are operatively connected to (or mated with) the busbar tip (153) (in order to, at least, receive electric power from the busbar (146)).

In one or more embodiments, the data exchange between the storage device (e.g., 185, FIG. 1.11) and, for example, the NOS-grub (e.g., 182, FIG. 1.11) may be enabled to manage a NOS boot sequence with the storage device (e.g., 185, FIG. 1.11) (in order to boot the NOS (or the BAS-NOS) from the storage device).

In one or more embodiments, as being a computing device, the ITC (175) includes the processor (170), the first storage/memory resource (171), the second storage/memory resource (172A), the third storage/memory resource (172B), the BIOS (e.g., 186, FIG. 1.11), the connection mechanism (154A) that includes two connectors (154B-C), and the socket connector (157). The aforementioned components may have the same or substantially the same functionality as the liked named components in FIG. 1.7.

Turning now to FIG. 1.11, FIG. 1.11 shows a diagram of ITC plugged into the busbar in accordance with one or more embodiments disclosed herein.

In one or more embodiments, as being a physical hardware component, the busbar (146) hosts, at least, the busbar tip (153) and the enclosure (165), which hosts the storage device (or the BAS) (185) (e.g., an NVMe M.2 SSD) and the connector (163). Further, as being a computing device, the ITC (175) includes the processor (170), the first storage/memory resource (171), the second storage/memory resource (172A), the third storage/memory resource (172B), the BIOS (186) (e.g., a UEFI BIOS), the connection mechanism (154A) (that acts a power rail to receive electric power from the busbar via the busbar tip (153)), and the socket connector (157). The aforementioned components may have the same or substantially the same functionality as the liked named components in FIG. 1.7.

In one or more embodiments, the storage device (185) may store data (e.g., user credentials, network packet traces that may include sensitive user data, data related to custom containers or business logic, etc.) and host a main NOS (or the BAS-NOS) that manages an operation of the ITC (175), in which the main NOS can be configured to be executed entirely off the BAS (as the BAS-NOS). Further, if the main NOS is functional, the ITC (via its NOS-grub (182)) can use the main NOS to boot itself up and make itself operable (without going through the configuration process with the ZTP server (e.g., 120, FIG. 1.1)).

In one or more embodiments, the BAS-NOS may include any program of executable instructions (or aggregation of programs of executable instructions) configured to manage and/or control the allocation and usage of hardware resources such as memory, processor time, disk space, and input/output devices, and provide an interface between such hardware resources and applications hosted by the BAS-NOS.

In one or more embodiments, the first storage/memory resource (171) includes a diagnostics module (180) (which includes one or more diagnostics tests for the ITC (175)), a NOS install agent (181) (which may have a functionality to install a BAS-NOS), and the NOS-grub (182) (a boot loader that chainloads into the BAS-NOS). During manufacturing of the ITC (175), the vendor (e.g., 125, FIG. 1.1) may install the diagnostics module (180), the NOS install agent (181), and the NOS-grub (182) (indicating that these components are preinstalled) and then ship the ITC (175) to a related user/customer.

In one or more embodiments, when there is an issue (e.g., a firmware related issue, a processor related issue (or a processor errata), a DRAM issue in the first storage/memory resource, a switchport cage connector issue, a management port/console issue, etc.) with the ITC (175), the user may instruct (via a GUI of a corresponding client (e.g., 110A, FIG. 1.1)) the diagnostics module (180) to perform a set of tests (e.g., a processor performance test, a memory performance test, a network traffic pattern test, etc.) on the ITC (175) to infer the health status/state of the ITC (175) and/or troubleshoot the issue.

One of ordinary skill will appreciate that each of the diagnostics module (180), the NOS install agent (181), and the NOS-grub (182) may perform other functionalities without departing from the scope of the embodiments disclosed herein.

FIG. 2 shows a method for managing a BAS (more specifically, managing a NOS boot sequence with the BAS) in accordance with one or more embodiments disclosed herein. While various steps in the method are presented and described sequentially, those skilled in the art will appreciate that some or all of the steps may be executed in different orders, may be combined or omitted, and some or all steps may be executed in parallel without departing from the scope of the embodiments disclosed herein.

Turning now to FIG. 2, the method shown in FIG. 2 may be executed (i) after an ITC (e.g., a network switch) is plugged into the busbar (where (a) all the connectors (e.g., 157, FIG. 1.11) of the ITC are operatively connected to the connectors (e.g., 163, FIG. 1.11) of the enclosure and (b) the two connectors of the connection mechanism (e.g., 154A, FIG. 1.11) are operatively connected to the busbar tip (e.g., 153, FIG. 1.11)) and powered on/up, and (ii) by, for example, the above-discussed processor (e.g., 170, FIG. 1.11), BIOS (e.g., 186, FIG. 1.11), and NOS install agent (or NOS agent) (e.g., 181, FIG. 1.11). Other components of the system (100) illustrated in FIG. 1.1 may also execute all or part of the method shown in FIG. 2 without departing from the scope of the embodiments disclosed herein.

In Step 200, the processor boots the BIOS. In Step 202, the BIOS boots the NOS install agent into an installation mode (in order to initiate a discovery process), in which the installation mode is an ONIE installation mode.

In Step 204, as part of the discovery process and by implementing a set of provisioning mechanisms (to ensure the ITC (as well as any other network elements supporting ITC's access to the network (e.g., 130, FIG. 1.1)) are appropriately provisioned to enable to ITC to perform its functionalities), the NOS install agent makes a first determination (in real-time or near real-time) as to whether a NOS-grub entry is missing in the storage device (e.g., 185, FIG. 1.11) and no BAS-NOS (or no main NOS) is present in the storage device (or in the BAS).

Accordingly, in one or more embodiments, if the result of the first determination is YES (indicating that the ITC (e.g., a newly received ITC (that supports the BAS) from the vendor (e.g., 125, FIG. 1.1), a replacement ITC (that supports the BAS) received from the vendor, etc.) is plugged into a different rack by the user), the method proceeds to Step 206. If the result of the first determination is NO (indicating that the user is swapped a faulty ITC with a replacement ITC (that supports the BAS) received from the vendor as part of an RMA procedure), the method proceeds to Step 210.

In one or more embodiments, the faulty ITC may be failed because of, for example (but not limited to): a CPU errata, a DRAM issue, a switchport cage connector issue, a management port issue, etc.

In Step 206, as a result of the first determination in Step 204 being YES, the NOS install agent communicates with the ZTP server (e.g., 120, FIG. 1.1) (which is managed by the vendor) to configure the ITC (e.g., the IT gear) by (i) adding the NOS-grub entry to the storage device and (ii) installing the BAS-NOS to the BAS (the storage device located in the enclosure). In Step 208, using the NOS-grub entry, the NOS install agent boots the BAS-NOS (from the storage device) to make the ITC operable. Once the ITC becomes operable, the NOS install agent may send a notification, via a GUI of a client device (e.g., 110A, FIG. 1.1), to the user to indicate that the ITC is ready to use. In one or more embodiments, the method may end following Step 208.

In Step 210, as a result of the first determination in Step 204 being NO, the NOS install agent determines that NOS-grub entry is missing but the BAS-NOS is present in the storage device. In Step 212, based on Step 210, the NOS install agent sends a set of information to the ZTP server. In one or more embodiments, the set of information may include/specify, for example (but not limited to): information with respect to a compute resource set (e.g., processing capability, storage capability, etc.) of the NOS install agent, an identifier of the storage device (located in the enclosure), information with respect to the storage device, information with respect to the BAS-NOS, an identifier of a rack (e.g., 142, FIG. 1.2) that the ITC is plugged into, etc.

In Step 214, based on Step 212, the NOS install agent receives a response from the ZTP server. In one or more embodiments, in the response, the ZTP server may indicate that (i) the ZTP server has approved the BAS-NOS based on the set of information, or (ii) the BAS-NOS has not been approved by the ZTP server based on the set of information.

Based on the response, the NOS install agent makes a second determination (in real-time or near real-time) as to whether the BAS-NOS has been approved (by the ZTP server). Accordingly, in one or more embodiments, if the result of the second determination is YES, the method proceeds to Step 216. If the result of the second determination is NO, the method returns to Step 206.

In Step 216, as a result of the second determination in Step 214 being YES, the NOS install agent updates the NOS-grub entry to obtain an updated NOS-grub entry using information with respect to the BAS-NOS. In one or more embodiments, the information with respect to the BAS-NOS may be retrieved from the BAS. Thereafter, the method may return to Step 208, in which, using the updated NOS-grub entry, the NOS install agent boots the BAS-NOS to make the ITC operable.

FIG. 3 shows a method for managing a BAS (more specifically, managing a NOS-grub boot sequence with the BAS) in accordance with one or more embodiments disclosed herein. While various steps in the method are presented and described sequentially, those skilled in the art will appreciate that some or all of the steps may be executed in different orders, may be combined or omitted, and some or all steps may be executed in parallel without departing from the scope of the embodiments disclosed herein.

Turning now to FIG. 3, the method shown in FIG. 3 may be executed (i) after an ITC (e.g., a network switch) is plugged into the busbar (where (a) all the connectors (e.g., 157, FIG. 1.11) of the ITC are operatively connected to the connectors (e.g., 163, FIG. 1.11) of the enclosure and (b) the two connectors of the connection mechanism are operatively connected to the busbar tip) and powered on/up, and (ii) by, for example, the above-discussed processor, BIOS, NOS install agent, and NOS-grub (e.g., 182, FIG. 1.11). Other components of the system (100) illustrated in FIG. 1.1 may also execute all or part of the method shown in FIG. 3 without departing from the scope of the embodiments disclosed herein.

In Step 300, the processor boots the BIOS. In Step 302, the BIOS boots the NOS-grub. In Step 304, the NOS-grub determines (e.g., makes a first determination) that the BAS is present. In Step 306, based on Step 304, the NOS-grub makes a second determination (in real-time or near real-time) as to whether the BAS (e.g., 185, FIG. 1.11) has a BAS-NOS (or a main NOS). Accordingly, in one or more embodiments, if the result of the second determination is YES, the method proceeds to Step 316. If the result of the second determination is NO, the method proceeds to Step 308.

In Step 308, as a result of the second determination in Step 306 being NO, the NOS-grub boots the NOS install agent into the installation mode (in order to initiate a discovery process). In Step 310, the NOS install agent communicates with the ZTP server to configure the ITC by (i) adding the NOS-grub entry to the storage device (or to the BAS) and (ii) installing the BAS-NOS to the BAS.

In Step 312, using the NOS-grub entry, the NOS install agent boots the BAS-NOS (from the storage device) to make the ITC operable. Once the ITC becomes operable, the NOS install agent may send a notification, via a GUI of a client device (e.g., 110A, FIG. 1.1), to the user to indicate that the ITC is ready to use. In one or more embodiments, the method may end following Step 312.

In Step 316, as a result of the second determination in Step 306 being YES, the NOS-grub makes a third determination (in real-time or near real-time) as to whether the NOS-grub entry is matched with information with respect to the BAS-NOS. Accordingly, in one or more embodiments, if the result of the third determination is YES, the method returns to Step 312. If the result of the third determination is NO, the method proceeds to Step 318.

In Step 318, as a result of the third determination in Step 316 being NO, the NOS-grub sends a set of information to the ZTP server. In one or more embodiments, the set of information may include/specify, for example (but not limited to): information with respect to a compute resource set of the NOS install agent, an identifier of the storage device (located in the enclosure), information with respect to the storage device, information with respect to the BAS-NOS, an identifier of a rack that the ITC is plugged into, etc.

In Step 320, based on the sending in Step 318, the NOS-grub receives a response from the ZTP server. In one or more embodiments, in the response, the ZTP server may indicate that (i) the ZTP server has approved the BAS-NOS based on the set of information, or (ii) the BAS-NOS has not been approved by the ZTP server based on the set of information.

Based on the response, the NOS-grub makes a fourth determination (in real-time or near real-time) as to whether the BAS-NOS has been approved (by the ZTP server). Accordingly, in one or more embodiments, if the result of the fourth determination is YES, the method proceeds to Step 322. If the result of the fourth determination is NO, the method returns to Step 308.

In Step 322, as a result of the fourth determination in Step 320 being YES, the NOS-grub updates the NOS-grub entry to obtain an updated NOS-grub entry using information with respect to the BAS-NOS. In one or more embodiments, the information with respect to the BAS-NOS may be retrieved from the BAS. Thereafter, the method may return to Step 312, in which, using the updated NOS-grub entry, the NOS install agent boots the BAS-NOS to make the ITC operable.

Turning now to FIG. 4, FIG. 4 shows a diagram of a computing device in accordance with one or more embodiments disclosed herein.

In one or more embodiments disclosed herein, the computing device (400) may include one or more computer processors (402), non-persistent storage (404) (e.g., volatile memory, such as RAM, cache memory), persistent storage (306) (e.g., a non-transitory computer readable medium, a hard disk, an optical drive such as a CD drive or a DVD drive, a Flash memory, etc.), a communication interface (412) (e.g., Bluetooth interface, infrared interface, network interface, optical interface, etc.), an input device(s) (410), an output device(s) (408), and numerous other elements (not shown) and functionalities. Each of these components is described below.

In one or more embodiments, the computer processor(s) (402) may be an integrated circuit for processing instructions. For example, the computer processor(s) (402) may be one or more cores or micro-cores of a processor. The computing device (400) may also include one or more input devices (410), such as a touchscreen, keyboard, mouse, microphone, touchpad, electronic pen, or any other type of input device. Further, the communication interface (412) may include an integrated circuit for connecting the computing device (400) to a network (e.g., a LAN, a WAN, Internet, mobile network, etc.) and/or to another device, such as another computing device.

In one or more embodiments, the computing device (400) may include one or more output devices (408), such as a screen (e.g., a liquid crystal display (LCD), plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (402), non-persistent storage (404), and persistent storage (406). Many different types of computing devices exist, and the aforementioned input and output device(s) may take other forms.

The problems discussed throughout this application should be understood as being examples of problems solved by embodiments described herein, and the various embodiments should not be limited to solving the same/similar problems. The disclosed embodiments are broadly applicable to address a range of problems beyond those discussed herein.

One or more embodiments disclosed herein may be implemented using instructions executed by one or more processors of a computing device. Further, such instructions may correspond to computer readable instructions that are stored on one or more non-transitory computer readable mediums.

While embodiments discussed herein have been described with respect to a limited number of embodiments, those skilled in the art, having the benefit of this Detailed Description, will appreciate that other embodiments can be devised which do not depart from the scope of embodiments as disclosed herein. Accordingly, the scope of embodiments described herein should be limited only by the attached claims.

What is claimed is:

1. A system, the system comprising:
a client;
a zero-touch provisioning (ZTP) server; and
an information handling system (IHS);
wherein the client, the ZTP server, and the IHS are operatively connected to each other over a network;
wherein the IHS comprises a rack, a busbar, an information technology component (ITC), and a set of computing devices,
wherein the rack is a housing for the set of computing devices,
wherein the busbar is affixed to a rear side of the rack,
wherein the busbar comprises an enclosure comprising a storage device and a heat sink,
wherein the storage device comprises a network operating system (NOS) that manages an operation of the ITC,
wherein, when the ITC is plugged into the busbar, a NOS grand unified bootloader (grub) of the ITC communicates with the storage device to boot up the NOS from the storage device to make the ITC operable, and
wherein the heat sink provides a temperature management to the storage device at least when the NOS is booted up.

2. The system of claim 1, wherein the busbar further comprises:
a rail that corresponds to a computing device of the set of computing devices; and
a busbar tip,
wherein the enclosure further comprises a first connector,
wherein the enclosure is slid along the rail to position the enclosure at a location on the busbar,
wherein the first connector is operatively connected to a second connector of the ITC in order to enable a data exchange between the storage device and the NOS-grub of the ITC, and
wherein a third connector of the ITC is operatively connected to the busbar tip in order to receive electric power from the busbar.

3. The system of claim 2, wherein the enclosure does not protrude beyond the busbar.

4. The system of claim 2, wherein the ITC is a network switch.

5. The system of claim 4, wherein the ITC is provided by a vendor that manages the ZTP server.

6. The system of claim 2, wherein a user is swapped a faulty ITC with the ITC that supports the storage device.

7. The system of claim 6, wherein the faulty ITC is failed because of at least one selected from a group consisting of a central processing unit (CPU) errata, a dynamic random access memory issue, a switchport cage connector issue, and a management port issue.

8. The system of claim 2, wherein a first shape of the rail enables the enclosure to firmly slide along the rail.

9. The system of claim 8, wherein the first shape of the rail matches with a second shape of the enclosure.

10. The system of claim 2,
wherein the busbar further comprises a set of threaded inserts,
wherein, after the enclosure is positioned to the busbar, a set of mechanical connection components is mounted to the set of threaded inserts to affix the enclosure to the busbar.

11. The system of claim 2, wherein the data exchange between the storage device and the NOS-grub is enabled to manage a network operating system boot sequence with the storage device.

12. The system of claim 11, wherein, in order to further manage the network operating system boot sequence, an agent of the ITC communicates with the ZTP server.

13. The system of claim 2, wherein a first distance between the first connector and the busbar tip is equal to a second distance between a midpoint of the third connector and the second connector.

14. An information handling system (IHS), the IHS comprising:
a rack;
a busbar;
an information technology component (ITC); and
a set of computing devices,
wherein the rack is a housing for the set of computing devices,
wherein the busbar is affixed to a rear side of the rack,
wherein the busbar comprises an enclosure comprising a storage device and a heat sink,
wherein the storage device comprises a network operating system (NOS) that manages an operation of the ITC,
wherein, when the ITC is plugged into the busbar, a NOS grand unified bootloader (grub) of the ITC communicates with the storage device to boot up the NOS from the storage device to make the ITC operable, and
wherein the heat sink provides a temperature management to the storage device at least when the NOS is booted up.

15. The IHS of claim 14, wherein the busbar further comprises:
a rail that corresponds to a computing device of the set of computing devices; and
a busbar tip,
wherein the enclosure further comprises a first connector,
wherein the enclosure is slid along the rail to position the enclosure at a location on the busbar,
wherein the first connector is operatively connected to a second connector of the ITC in order to enable a data exchange between the storage device and the NOS-grub of the ITC, and
wherein a third connector of the ITC is operatively connected to the busbar tip in order to receive electric power from the busbar.

16. The IHS of claim 15, wherein the enclosure does not protrude beyond the busbar.

17. The IHS of claim 15, wherein the ITC is a network switch.

18. The IHS of claim 15, wherein a first shape of the rail enables the enclosure to firmly slide along the rail.

19. The IHS of claim 18, wherein the first shape of the rail matches with a second shape of the enclosure.

20. The IHS of claim 15,
wherein the busbar further comprises a set of threaded inserts,
wherein, after the enclosure is positioned to the busbar, a set of mechanical connection components is mounted to the set of threaded inserts to affix the enclosure to the busbar.
